(19) United States
(12) Patent Application Publication
(10) Pub. No.: US 2025/0237945 A1
(43) Pub. Date: Jul. 24, 2025

(54) RESIST COMPOSITION AND METHOD OF FORMING PATTERN USING THE SAME

(71) Applicant: Samsung Electronics Co., Ltd., Suwon-si (KR)

(72) Inventors: Kyuhyun IM, Suwon-si (KR); Haengdeog KOH, Suwon-si (KR); Yoonhyun KWAK, Suwon-si (KR); Beomseok KIM, Suwon-si (KR); Changki KIM, Suwon-si (KR); Youngmin NAM, Suwon-si (KR); Aram JEON, Suwon-si (KR); Jinwon JEON, Suwon-si (KR); Minyoung HA, Suwon-si (KR)

(73) Assignee: Samsung Electronics Co., Ltd., Suwon-si (KR)

(21) Appl. No.: 18/769,750

(22) Filed: Jul. 11, 2024

(30) Foreign Application Priority Data
Jan. 23, 2024 (KR) 10-2024-0010397

(51) Int. Cl. G03F 7/004; G03F 7/20

(52) U.S. Cl. CPC G03F 7/0042; G03F 7/0045; G03F 7/2004

(57) ABSTRACT

Provided are a resist composition including an organometallic compound represented by the following Formula 1 and an additive represented by the following Formula 2, and a pattern formation method using the same:

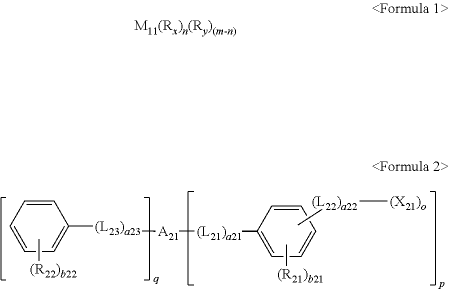

wherein in Formulae 1 and 2, M₁₁, Rₓ, R_{y}, n, m, A₂₁, L₂₁ to L₂₃, a21 to a23, R₂₁, R₂₂, b21, b22, X₂₁, o, p and q are as described in the specification.

### CROSS-REFERENCE TO RELATED APPLICATION

This application is based on and claims priority under 35 USC § 119 to Korean Patent Application No. 10-2024-0010397, filed on Jan. 23, 2024, in the Korean Intellectual Property Office, the disclosure of which is incorporated by reference herein in its entirety.

### BACKGROUND

### 1. Field

The disclosure relates to resist compositions and methods of forming patterns by using the same.

### 2. Description of the Related Art

During manufacturing of semiconductors, resists, of which physical properties change in response to light, are being used to form fine patterns. Among the resists, chemically amplified resists have been widely used. In the case of chemically amplified resists, an acid formed through a reaction between light and a photoacid generator reacts with a base resin again to change the solubility of the base resin with respect to a developer, thereby enabling patterning.

However, in the case of chemically amplified resists, the diffusion of the formed acid into non-exposed areas may lead to poor pattern uniformity and increased surface roughness. In addition, with increasingly miniaturized semiconductor processes, it is not easy to control the diffusion of acids, resulting in the need to develop a new type of resist.

Recently, in order to overcome the limits of chemically amplified resists, attempts have been made to develop materials of which physical properties change due to exposure to light. However, the dose required for exposure is still high.

### SUMMARY

Provided are resist compositions which may have improved storage stability, whose properties change even with low doses of exposure, and which provide patterns of improved resolution, and methods of forming patterns using the same.

Additional aspects will be set forth in part in the description which follows and, in part, will be apparent from the description, or may be learned by practice of the presented example embodiments of the disclosure.

According to some inventive concepts, a resist composition may include
an organometallic compound represented by Formula 1; and
an additive represented by Formula 2;

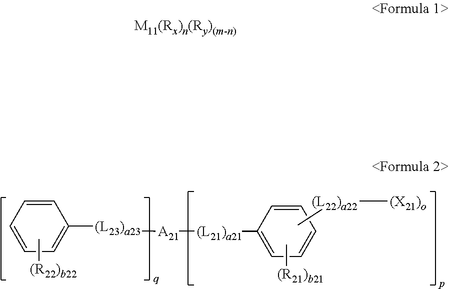

wherein in Formulae 1 and 2,
M₁₁ is indium (In), tin (Sn), antimony (Sb), tellurium (Te), thallium (Tl), lead (Pb), bismuth (Bi), or polonium (Po),
Rₓ is *-(L₁)ₐ₁-(R₁)_{b1},
R_{y} is *-Y₁-X₁,
* is a bonding site with a neighboring atom of Formula 1,
n is an integer from 1 to 6,
m is an integer from 0 to 6,
m-n is greater than or equal to 0,
a plurality of Rₓ are the same or different from each other,
a plurality of R_{y} are the same or different from each other,
L₁ is a single bond, a linear or branched C₁-C₃₀ divalent hydrocarbon group, or a cyclic C₃-C₃₀ divalent hydrocarbon group,
a1 is an integer from 1 to 4,
R₁ is a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, substituted or unsubstituted C₃-C₃₀ heterocycloalkenyl group, substituted or unsubstituted C₂-C₃₀ alkynyl group, substituted or unsubstituted C₆-C₃₀ aryl group, substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
b1 is an integer from 1 to 4, such that Rₓ includes, a single R₁ based on b1 being 1, or a plurality of R₁ based on b1 being 2, 3, or 4, the plurality of R₁ being independently present or adjacent two of the plurality of R₁ being combined with each other to form a condensed ring,
Y₁ is O, O(C═O), S, S(C═O), NX₁₄ or N(C═O),
X₁ and X₁₄ are each independently hydrogen, deuterium, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom,
A₂₁ is a single bond, a substituted or unsubstituted carbon atom, a substituted or unsubstituted silicon atom, or (p+q)-valent bonding unit;
L₂₁ to L₂₃ are each independently a single bond; O; S; CO; CO₂; a hydroxyl group; a cyano group; a nitro group; a linear or branched C₁-C₃₀ divalent hydrocarbon group; a linear or branched C₁-C₃₀ divalent hydrocarbon group including a heteroatom; a cyclic C₃-C₃₀ divalent hydrocarbon group; a cyclic C₃-C₃₀ divalent hydrocarbon group including a heteroatom; a linear or branched C₁-C₃₁ monovalent hydrocarbon group; a linear or branched C₁-C₃₁ monovalent hydrocarbon group including a heteroatom, a cyclic C₃-C₃₁ monovalent hydrocarbon group; a cyclic C₃-C₃₁ monovalent hydrocarbon group including a heteroatom; or any combination thereof,
a21 to a23 are each independently an integer from 1 to 6;
R₂₁ and R₂₂ are each independently hydrogen, deuterium, a halogen atom, a hydroxyl group, a cyano group, a nitro group, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom,
b21 is an integer from 1 to 4,
b22 is an integer from 1 to 5,
X₂₁ is a substituted or unsubstituted C₁-C₃₀ alkyl group, a substituted or unsubstituted C₁-C₃₀ haloalkyl group, a substituted or unsubstituted C₂-C₃₀ alkenyl group, or a substituted or unsubstituted C₆-C₃₀ aryl group,
o is an integer from 1 to 10,
p is an integer from 0 to 10,
q is an integer from 0 to 10, and
A₂₁, L₂₁ to L₂₃, R₂₁, and R₂₂ are each independently present or adjacent two of A₂₁, L₂₁ to L₂₃, R₂₁, and R₂₂ are combined with each other to form a ring.
M₁₁ may be In, Sn, or Sb.
n may be an integer from 1 to 4, and m may be an integer from 0 to 3.
L₁ may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or substituted or unsubstituted C₁-C₃₀ heteroarylene group.
R₁ may be a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.
Y₁ may be O, O(C═O), S or S(C═O).

X₁ and X₁₄ may be each independently be hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

The organometallic compound represented by Formula 1 may be represented by any one of Formulae 1-1 to 1-4:

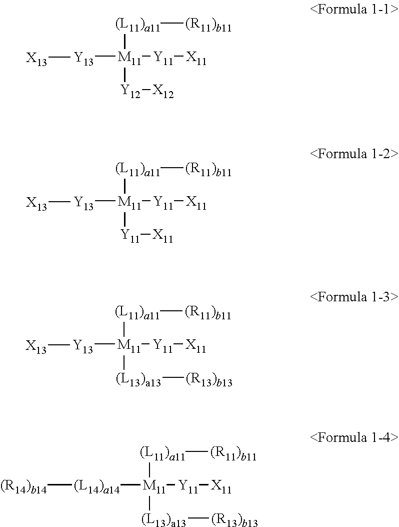

wherein in Formulae 1-1 to 1-4,
M₁₁ has a same composition as defined in Formula 1,
L₁₁ to L₁₄ each independently have a same composition as L₁ in Formula 1,
a₁₁ to a₁₄ each independently have a same composition as a₁ in Formula 1,
R₁₁ to R₁₄ each independently have a same composition as R₁ in Formula 1,
b₁₁ to b₁₄ each independently have a same composition as b₁ in Formula 1,
Y₁₁ to Y₁₃ each independently have a same composition as Y₁ in Formula 1, and
X₁₁ to X₁₄ each independently have a same composition as X₁ in Formula 1.

The organometallic compound represented by Formula 1 may be selected from Group I:

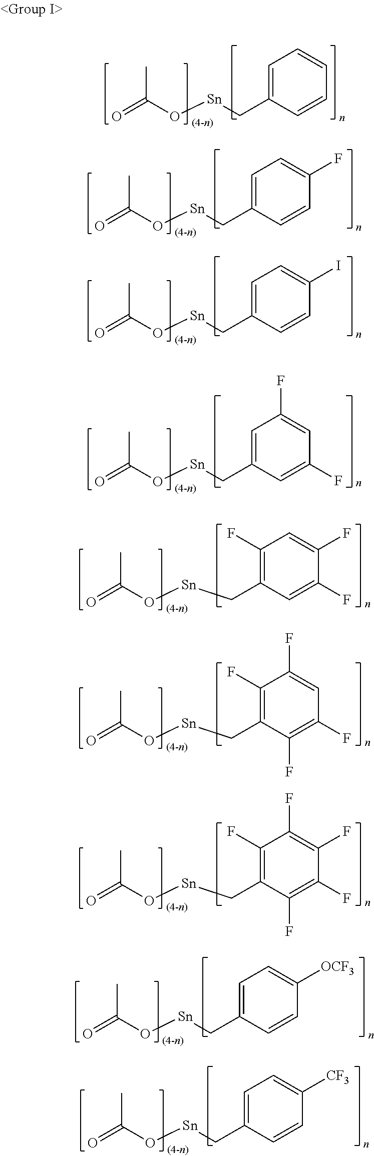

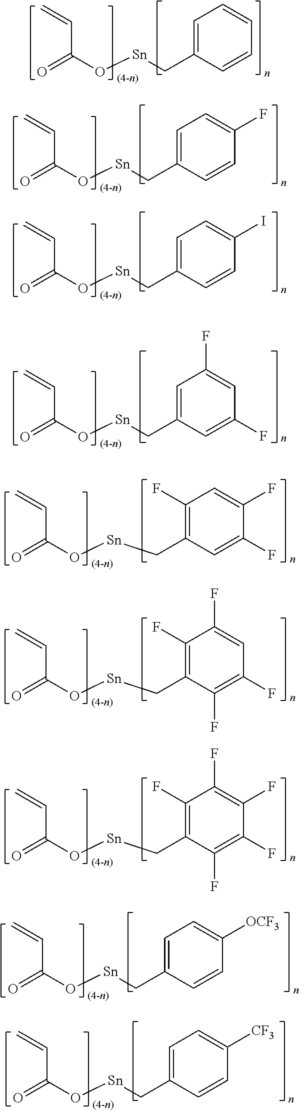

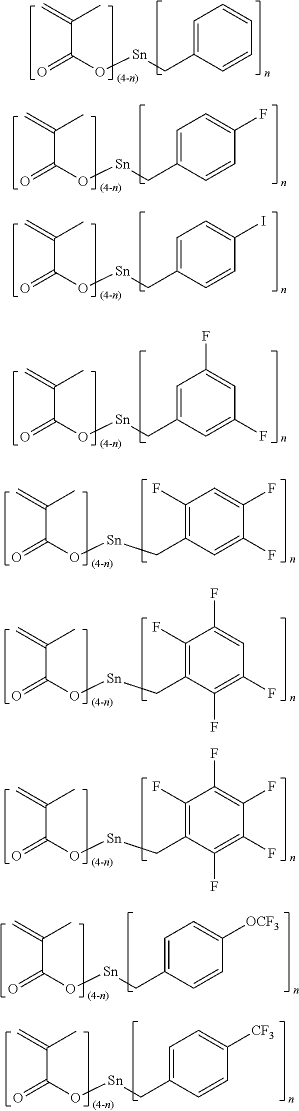

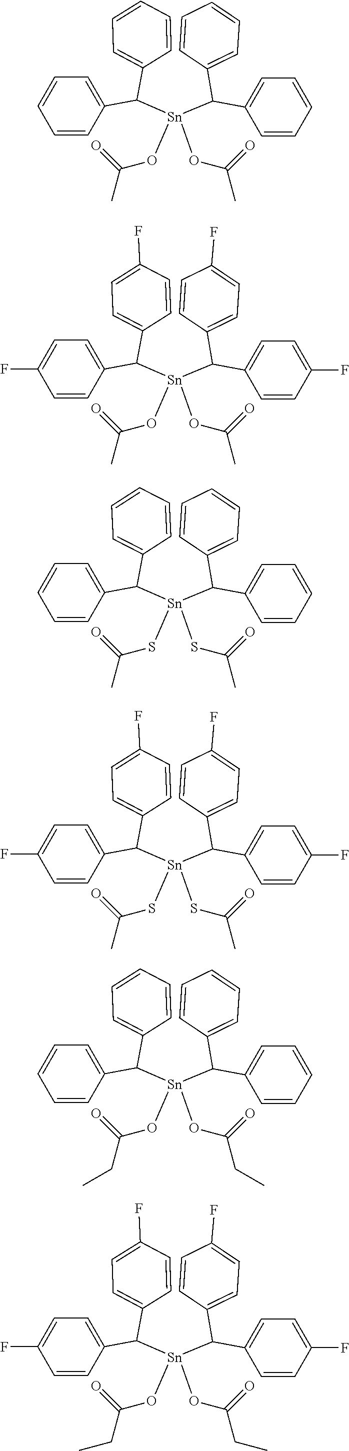

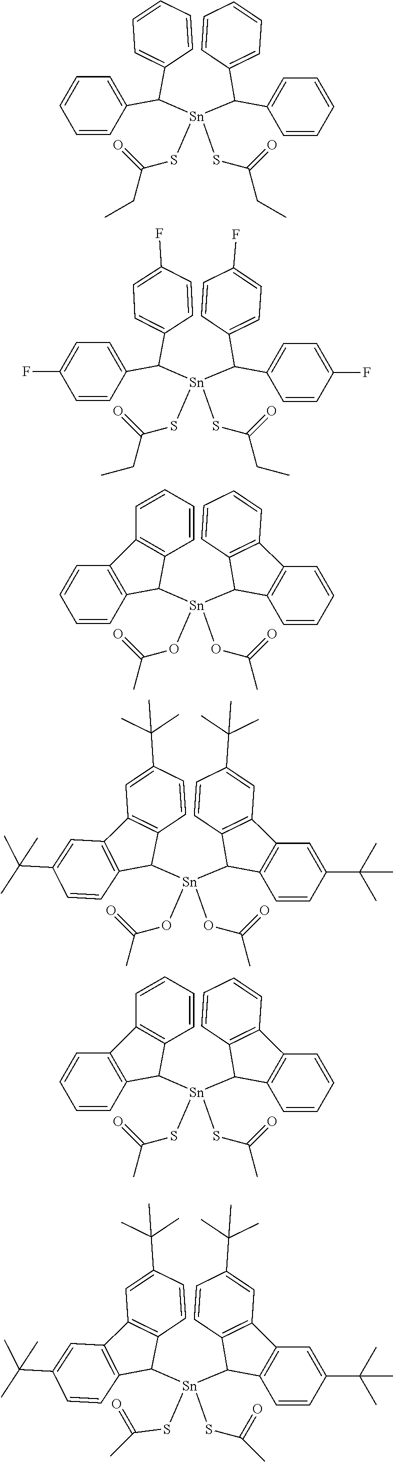

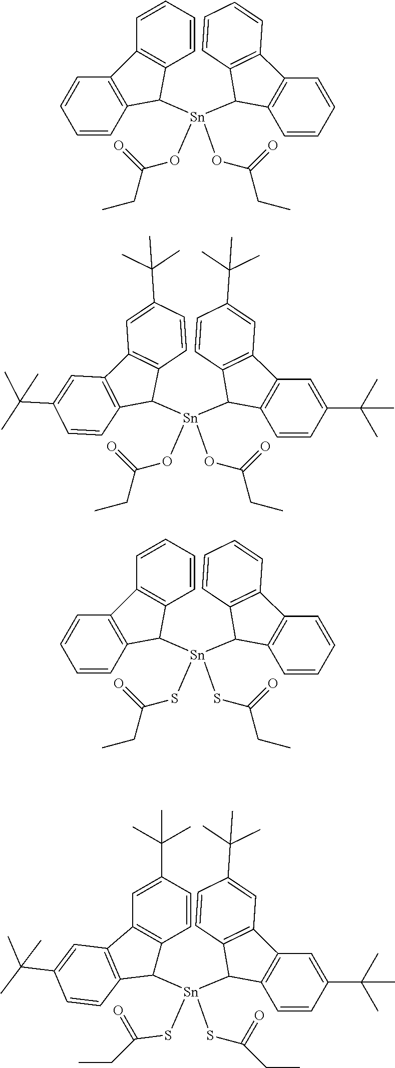

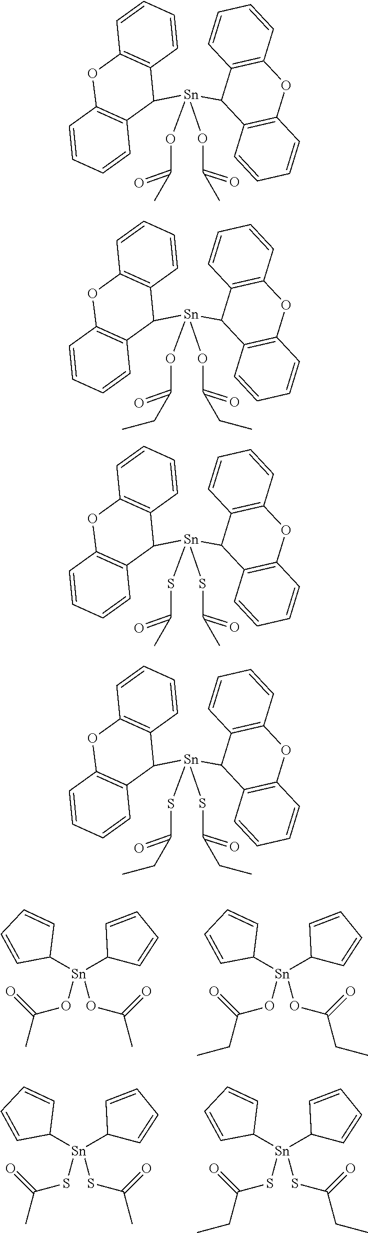

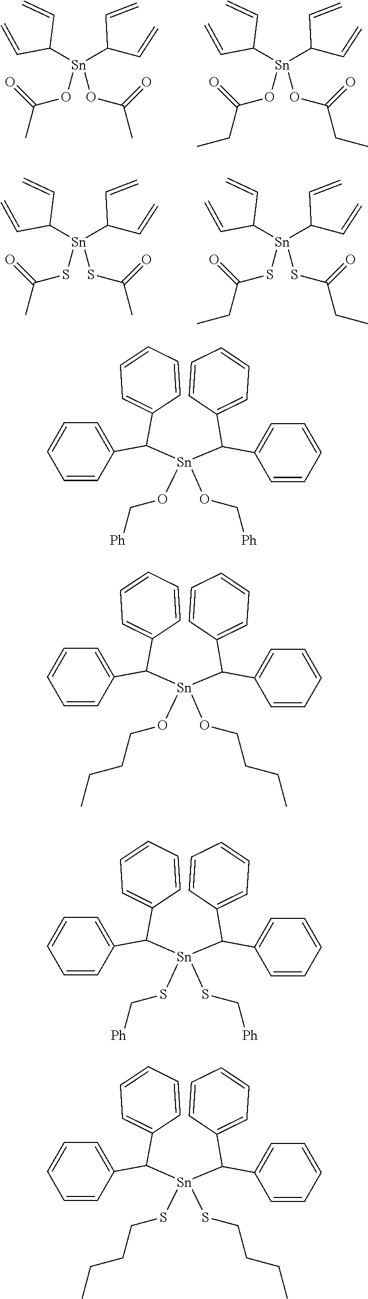

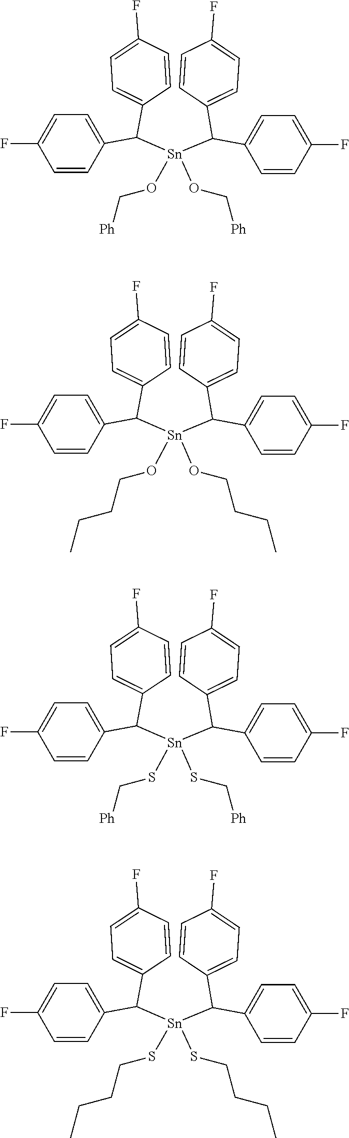 [SMILES: Fc1ccc([CH](c2ccc(F)cc2)[Sn]([O]Cc2ccccc2)([O]Cc2ccccc2)[CH](c2ccc(F)cc2)c2ccc(F)cc2)cc1 ; CCCC[O][Sn]([O]CCCC)([CH](c1ccc(F)cc1)c1ccc(F)cc1)[CH](c1ccc(F)cc1)c1ccc(F)cc1 ; Fc1ccc([CH](c2ccc(F)cc2)[Sn]([S]Cc2ccccc2)([S]Cc2ccccc2)[CH](c2ccc(F)cc2)c2ccc(F)cc2)cc1 ; CCCC[S][Sn]([S]CCCC)([CH](c1ccc(F)cc1)c1ccc(F)cc1)[CH](c1ccc(F)cc1)c1ccc(F)cc1]

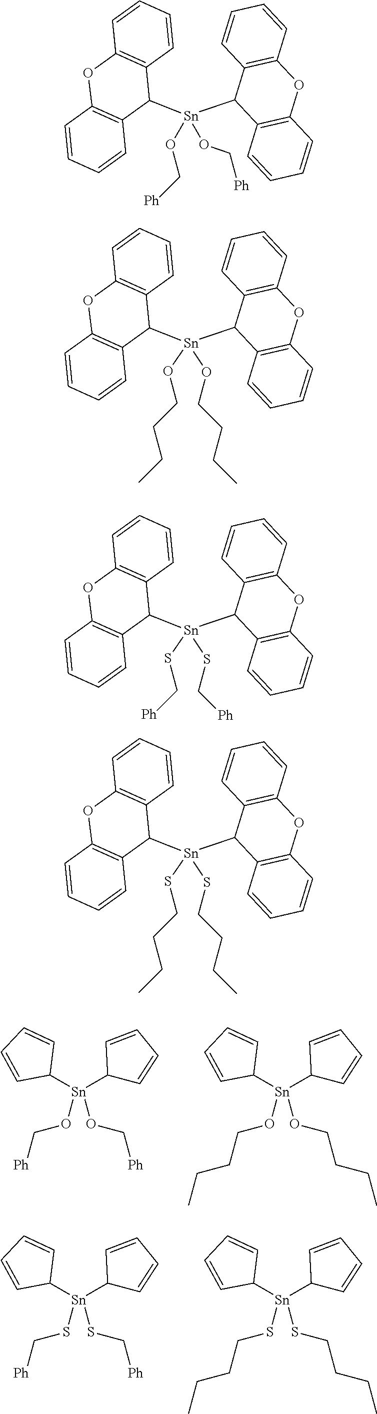

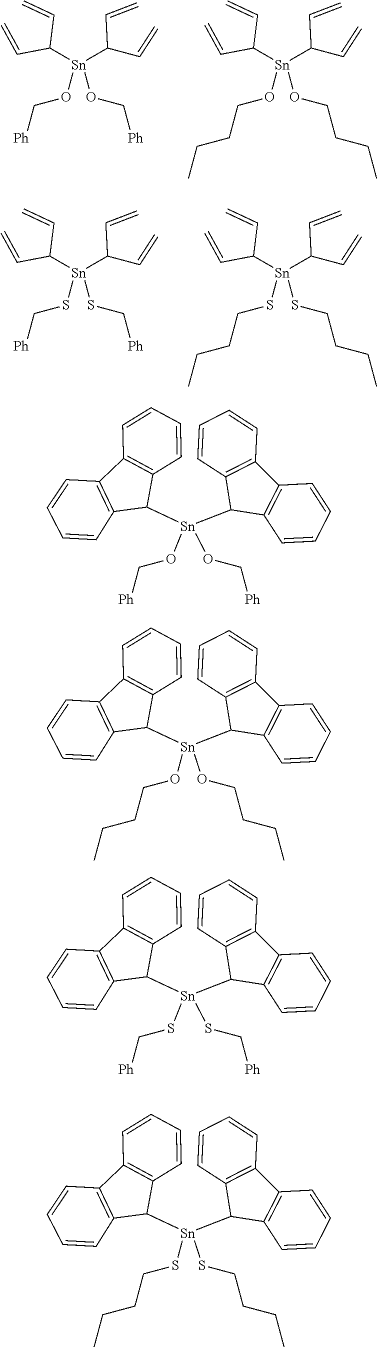

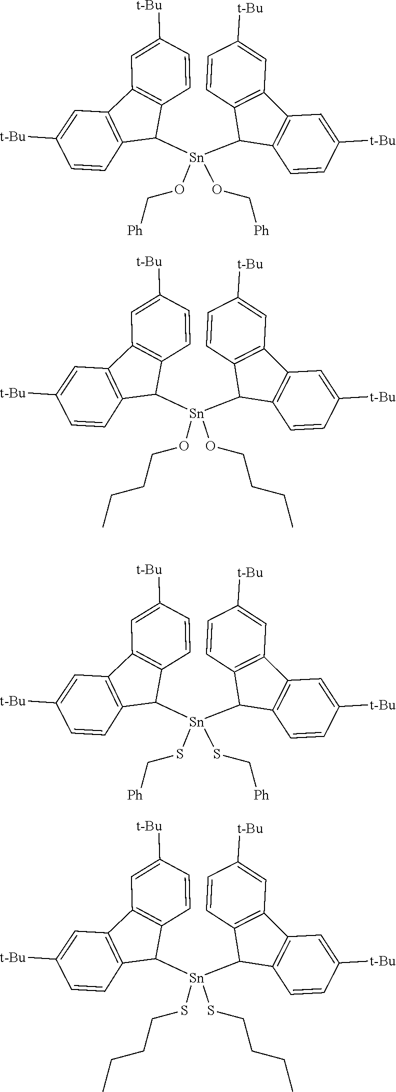

wherein in Group I, n is an integer from 1 to 4.
A₂₁ may be a single bond, a substituted or unsubstituted carbon atom, or (p+q)-valent bonding unit including at least one of a substituted or unsubstituted carbon atom or substituted or unsubstituted benzene as a repeating unit.
L₂₁ to L₂₃ may each independently be a single bond, O, S, CO, CO₂, CRₐR_{b}, or any combination thereof, and Ra and Rb may each independently be hydrogen, deuterium, a halogen atom, a hydroxyl group, a cyano group, a nitro group, or a linear or branched C₁-C₁₀ monovalent hydrocarbon group, a linear or branched C₁-C₁₀ monovalent hydrocarbon group including a heteroatom, a cyclic C₃-C₁₀ monovalent hydrocarbon group, or a cyclic C₃-C₁₀ monovalent hydrocarbon group including a heteroatom.
R₂₁ and R₂₂ may each independently be hydrogen, deuterium, a halogen atom, a hydroxyl group, a cyano group, a nitro group, a substituted or unsubstituted C₁-C₃₀ alkyl group, a substituted or unsubstituted C₃-C₃₀ cycloalkyl group, a substituted or unsubstituted C₂-C₃₀ alkenyl group, a substituted or unsubstituted C₃-C₃₀ cycloalkenyl group, a substituted or unsubstituted C₂-C₃₀ alkynyl group, or a substituted or unsubstituted C₆-C₃₀ aryl group.
X₂₁ may be a substituted or unsubstituted C₁-C₁ haloalkyl group, a substituted or unsubstituted vinyl group, or a group represented by Formula 5-1:

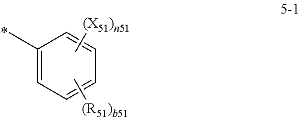

wherein in Formula 5-1,
X₅₁ is a halogen atom, a substituted or unsubstituted C₁-C₁₀ haloalkyl group, or a substituted or unsubstituted vinyl group,
n51 is an integer from 1 to 5,
R₅₁ is hydrogen, deuterium, a halogen atom, a hydroxyl group, a substituted or unsubstituted C₁-C₁ haloalkyl group, or a substituted or unsubstituted vinyl group,
b51 is an integer from 0 to 4, and
* is a bonding site with a neighboring atom of Formula 2.

The additive represented by Formula 2 may be represented by Formula 2-1:

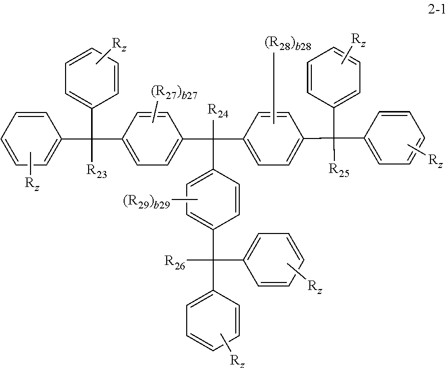

wherein in Formula 2-1,
R_{z} is selected from R₂₂ and (L₂₂)ₐ₂₂-(X₂₁)ₒ, at least one of R_{z} is (L₂₂)ₐ₂₂-(X₂₁)ₒ,
R₂₂ to R₂₉ are each independently the same as the definition of R₂₂ in Formula 2, and
b27 to b29 are each independently an integer of 1 to 4.

The additive represented by Formula 2 may be selected from Group II:

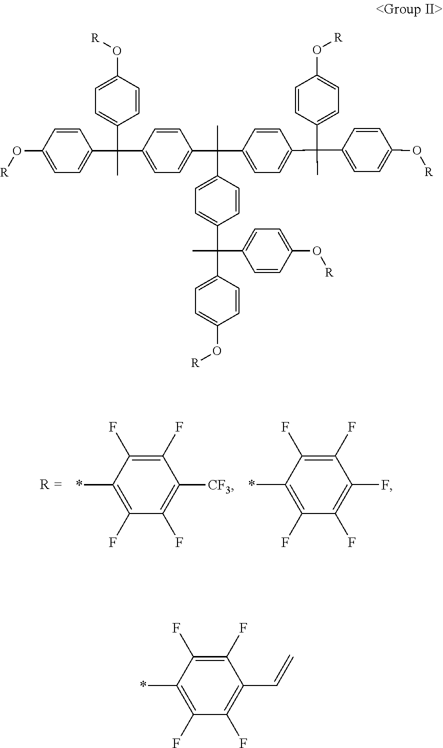

wherein in Group II,
* is a bonding site with a neighboring atom of Formula 2, and
each R is independently one of

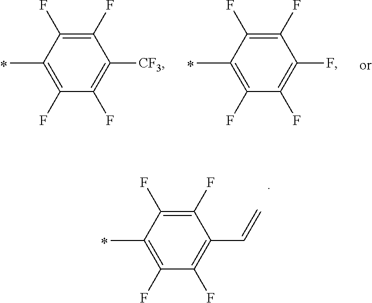

The additive may be included in an amount of 0.1 parts by weight to 100,000 parts by weight, based on 100 parts by weight of the organometallic compound.

According to some example embodiments, a method of forming a pattern may include: applying the resist composition of claim 1 onto a substrate to form a resist film; exposing at least a portion of the resist film to high-energy rays to provide an exposed resist film; and developing the exposed resist film using a developer.

The exposing at least a portion of the resist film may be performed based on irradiating the resist film using at least one of deep ultraviolet rays (DUV), extreme ultraviolet rays (EUV), electron beams (EBs), or any combination thereof.

The organometallic compound may be subjected to a condensation reaction based on exposing the resist film.

The exposed resist film may include an exposed portion and a non-exposed portion, and in the developing, the non-exposed portion is removed.

### BRIEF DESCRIPTION OF THE DRAWINGS

The above and other aspects, features, and advantages of some example embodiments of the inventive concepts will be more apparent from the following description taken in conjunction with the accompanying drawings, in which:

FIG. 1 is a flowchart illustrating a method of forming a pattern, according to some example embodiments, and

FIGS. 2A to 2C are side cross-sectional views illustrating a method of forming a pattern, according to some example embodiments.

### DETAILED DESCRIPTION

Reference will now be made in detail to some example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

Since the disclosure can apply various transformations and have various example embodiments, specific example embodiments will be illustrated in the drawings and described in detail in the detailed description. However, it should be understood that this is not intended to limit the disclosure to specific example embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these terms are only used to distinguish one element from another element, and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

The expression “Cₓ-C_{y}” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

As used herein, when a definition is not otherwise provided, “ester group” refers to a group represented by —C(═O)OR, wherein R is a C₁ to C₂₀ alkyl group or a C₆ to C₂₀ aryl group.

As used herein, when a definition is not otherwise provided, “combination thereof” in the definition of chemical formula refers to at least two substituents bound to each other by a single bond or a C₁ to C₁₀ alkylene group, or at least two fused substituents.

As used herein, when a definition is not otherwise provided, “amide group” refers to a group represented by —C(═O)NR, wherein R may be a C₁ to C₂₀ alkyl group or a C₆ to C₂₀ aryl group.

The term “monovalent hydrocarbon group” used herein refers to a monovalent residue derived from an organic compound including carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e. g., a phenyl group, a 1-naphthyl group, and a 2-naphthyl group); an arylalkyl group (e. g., a benzyl group and a diphenylmethyl group); a heteroatom-including monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or any combination thereof. Additionally, some of hydrogens in these groups may be substituted by a moiety including a heteroatom such as oxygen, sulfur, nitrogen, phosphorus or halogen atoms, or some of carbons in these groups may be replaced by a moiety including a heteroatom such as oxygen, sulfur, nitrogen, or phosphorus, and thus these groups may include a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, etc.

The term “divalent hydrocarbon group” as used herein is a divalent residue and refers to a system in which any one hydrogen atom of the monovalent hydrocarbon group is replaced with a bonding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof may include a methyl group, an ethyl group, a propyl group, an isobutyl group, a sec-butyl group, a tert-butyl group, a pentyl group, an iso-amyl group, and/or a hexyl group.

The term “alkylene group” as used herein refers to a linear or branched saturated aliphatic divalent hydrocarbon group, and examples thereof may include a methylene group, an ethylene group, a propylene group, a butylene group, and/or an isobutylene group.

The term “halogenated alkyl group” as used herein refers to a group in which at least one substituent of an alkyl group is substituted with a halogen atom, and/or examples thereof include CF₃. In this regard, the halogen atom is F, Cl, Br, or I.

The term “alkoxy group” as used herein refers to a monovalent group having a formula of —OA₁₀₁, wherein A₁₀₁ is an alkyl group. Specific examples thereof include a methoxy group, an ethoxy group, an isopropyloxy group, and/or the like.

The term “alkylthio group” as used herein refers to a monovalent group having a formula of —SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof include —OCF₃ and/or the like.

The term “halogenated alkylthio group” as used herein refers to a group in which one or more hydrogen atoms of an alkylthio group are substituted with a halogen atom, and specific examples thereof include —SCF₃ and/or the like.

As used herein, when a definition is not otherwise provided, “aromatic ring” refers to a C₆ to C₁₀ hydrocarbon cyclic group (e.g., a C₆ to C₁₀ aryl group) providing a conjugated structure or a C₂ to C₁₀ heterocyclic group (e.g., a C₂ to C₁₀ heteroaryl group) providing a conjugated structure.

As used herein, “hydrocarbon cyclic group” may be a C₃ to C₃₀ hydrocarbon cyclic group. The hydrocarbon cyclic group may be an aromatic hydrocarbon cyclic group (e.g., C₆ to C₃₀ arene group, C₆ to C₂₀ arene group, or C₆ to C₁₀ arene group or C₆ to C₃₀ aryl group, C₆ to C₂₀ aryl group, or C₆ to C₁₀ aryl group), an alicyclic hydrocarbon cyclic group (e.g., C₃ to C₃₀ cycloalkyl group, C₅ to C₃₀ cycloalkyl group, C₃ to C₂₀ cycloalkyl group, or C₃ to C₁₀ cycloalkyl group), or a fused ring group thereof. For example, the fused ring group may refer to a fused ring of an aromatic ring (arene ring) and a non-aromatic ring (alicyclic ring), for example a fused ring in which at least one aromatic ring (arene ring) such as a C₆ to C₃₀ arene group, a C₆ to C₂₀ arene group, or a C₆ to C₁₀ arene group or a C₆ to C₃₀ aryl group, a C₆ to C₂₀ aryl group, or a C₆ to C₁₀ aryl group and at least one non-aromatic ring (alicyclic ring) such as a C₃ to C₃₀ cycloalkyl group, a C₃ to C₂₀ cycloalkyl group, or a C₃ to C₁₀ cycloalkyl group are fused to each other.

As used herein, when a definition is not otherwise provided, “aromatic hydrocarbon group” includes a phenyl group, a naphthyl group, a C₆ to C₃₀ aryl group, a C₆ to C₃₀ arylene group, but is not limited thereto.

As used herein, when a definition is not otherwise provided, “fused ring” is a fused ring of two or more substituted or unsubstituted C₅ to C₃₀ hydrocarbon cyclic groups, a fused ring of two or more substituted or unsubstituted C₂ to C₃₀ heterocyclic groups, or a fused ring of a substituted or unsubstituted C₅ to C₃₀ hydrocarbon cyclic group and a substituted or unsubstituted C₂ to C₃₀ heterocyclic group (e.g., a fluorenyl group). Herein, the hydrocarbon cyclic group is as defined above.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and/or the like.

The term “cycloalkoxy group” as used herein refers to a monovalent group having a formula of —OA₁₀₂, wherein A₁₀₂ is a cycloalkyl group. Specific examples thereof include a cyclopropoxy group, a cyclobutoxy group, and/or the like.

The term “cycloalkylthio group” as used herein refers to a monovalent group having a formula of —SA₁₀₂, wherein A₁₀₂ is a cycloalkyl group.

As used herein, a “heterocycloalkyl group” may be one in which some carbons of the cycloalkyl group are replaced by a moiety including a heteroatom, such as oxygen, sulfur, or nitrogen, and the heterocycloalkyl group specifically includes an ether bond, an ester linkage, sulfonic acid ester linkage, carbonate, lactone ring, sultone ring, or carboxylic anhydride moiety.

The term “heterocycloalkylene group” as used herein refers to a group in which some carbon atoms of the cycloalkylene group are replaced by a moiety including a heteroatom, for example, oxygen, sulfur, or nitrogen.

The term “heterocycloalkoxy group” as used herein refers to a monovalent group having a formula of —OA₁₀₃, wherein A₁₀₃ is a heterocycloalkyl group.

The term “heterocycloalkylthio group” as used herein refers to a monovalent group having the formula of —SA₁₀₃ wherein A₁₀₃ may be a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

The term “heterocycloalkenyl group” as used herein refers to a group in which some carbon atoms of the cycloalkenylene group are replaced by a moiety including a heteroatom, for example, oxygen, sulfur, or nitrogen. The term “heterocycloalkenylene group” as used herein refers to a group in which some carbon atoms of the cycloalkenylene group are replaced by a moiety including a heteroatom, for example, oxygen, sulfur, or nitrogen.

The term “alkynyl group” as used herein refers to a linear or branched unsaturated aliphatic hydrocarbon monovalent group including one or more carbon-carbon triple bonds.

The term “aryl group” as used herein refers to a monovalent group having a carbocyclic aromatic system, and examples thereof include a phenyl group, a naphthyl group, anthracenyl group, a phenanthrenyl group, a pyrenyl group, and/or a chrysenyl group.

The term “arylene group” as used herein refers to a divalent group having a carbocyclic aromatic system.

The term “aryloxy group” as used herein refers to a monovalent group represented by —OA₁₀₄, wherein A₁₀₄ is an alkyl group.

The term “arylthio group” as used herein refers to a monovalent group represented by —SA₁₀₄, wherein A₁₀₄ is an alkyl group.

The term “heteroaryl group” as used herein refers to a monovalent group having a heterocyclic aromatic system, and specific examples thereof include a pyridinyl group, a pyrimidinyl group, a pyrazinyl group, and/or the like.

The term “heteroarylene group” as used herein refers to a divalent group having a heterocyclic aromatic system.

The term “heteroaryloxy group” as used herein refers to a monovalent group represented by —OA₁₀₅, wherein A₁₀₅ is a heteroaryl group.

The term “heteroarylthio group” as used herein refers to a monovalent group represented by —SA₁₀₅, wherein A₁₀₅ is a heteroaryl group.

The term “arylalkyl group” as used herein refers to a group in which an alkyl group is substituted with a monovalent group having a carbocyclic aromatic system, and specific examples include a benzyl group, a diphenylmethyl group, etc.

The term “heteroarylalkyl group” as used herein refers to a group in which an alkyl group is substituted with a monovalent group having a heterocyclic aromatic system.

The term “heterocyclic group” as used herein refers to a monocyclic or polycyclic group having 1 to 60 carbon atoms including at least one heteroatom, and is a group that includes a monovalent group, a divalent group, and a trivalent group.

The term “substituted” as used herein includes an atom or group which has a substituent bonded to the atom or group. For example, a substituted group may include a substituent that replaces a carbon or hydrogen atom in an unsubstituted atom or group corresponding to the unsubstituted atom or group. Substituent as used herein is defined below.

The term “substituent” as used herein, where not otherwise defined, includes a deuterium, oxygen, sulfur, a halogen atom such as fluorine, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a linear or branched C₃-C₃₁ monovalent hydrocarbon group, a linear or branched C₁-C₃₀ divalent hydrocarbon group, a cyclic C₃-C₃₀ monovalent hydrocarbon group, a cyclic C₃-C₃₀ divalent hydrocarbon group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and/or combinations thereof; a linear or branched C₃-C₃₁ monovalent hydrocarbon group, a linear or branched C₁-C₃₀ divalent hydrocarbon group, a cyclic C₃-C₃₀ monovalent hydrocarbon group, a cyclic C₃-C₃₀ divalent hydrocarbon group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with a deuterium, oxygen, sulfur, a halogen atom such as fluorine, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and/or any combination thereof; and/or any combination thereof.

Hereinafter, example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, example embodiments set forth herein are merely examples and various changes may be made therein.

In the drawings, parts having no relationship with the description are omitted for clarity, and the same or similar constituent elements are indicated by the same reference numeral throughout the specification.

In the drawings, the thickness of layers, films, panels, regions, etc., are exaggerated for clarity.

### [Resist Composition]

Resist compositions according to some example embodiments include an organometallic compound represented by Formula 1, and
an additive represented by Formula 2:

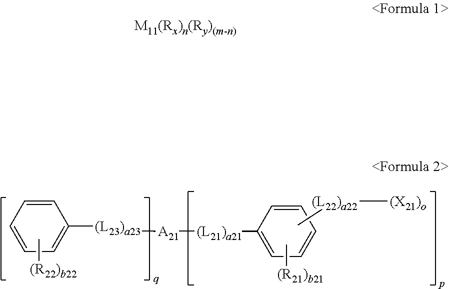

wherein, in Formulae 1 and 2,
M₁₁ may be indium (In), tin (Sn), antimony (Sb), tellurium (Te), thallium (Tl), lead (Pb), bismuth (Bi), or polonium (Po);
Rₓ may be *-(L₁)ₐ₁-(R₁)_{b1},
R_{y} may be *-Y₁-X₁,
* is a bonding site with a neighboring atom of Formula 1,
n may be an integer from 1 to 6,
m may be an integer from 0 to 6,
m-n may be greater than or equal to 0,
a plurality of Rₓ may be the same or different from each other,
a plurality of R_{y} may be the same or different from each other,
L₁ may be a single bond or a linear, branched or cyclic C₁-C₃₀ divalent hydrocarbon group, a1 may be an integer from 1 to 4,
R₁ may be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, substituted or unsubstituted C₃-C₃₀ heterocycloalkenyl group, substituted or unsubstituted C₂-C₃₀ alkynyl group, substituted or unsubstituted C₆-C₃₀ aryl group, substituted or unsubstituted C₇-C₃₀ arylalkyl group, a substituted or unsubstituted C₁-C₃₀ heteroaryl group, or a substituted or unsubstituted C₂-C₃₀ heteroarylalkyl group, and adjacent two of the plurality of R₁ may be optionally combined with each other to form a condensed ring,
b1 may be an integer from 1 to 4, such that Rₓ includes, a single R₁ based on b1 being 1, or a plurality of R₁ based on b1 being 2, 3, or 4, the plurality of R₁ being independently present or adjacent two of the plurality of R₁ being combined with each other to form a condensed ring,
Y₁ may be O, O(C═O), S, S(C═O), NX₁₄ or N(C═O),
X₁ and X₁₄ may each independently be a hydrogen, a deuterium, or a linear, branched or cyclic C₁-C₃₀ monovalent hydrocarbon group optionally including a heteroatom, A₂₁ may be a single bond, a substituted or unsubstituted carbon atom, a substituted or unsubstituted silicon atom, or a (p+q)-valent bonding unit,
L₂₁ to L₂₃ may each independently be a single bond; O; S; CO; CO₂; a linear, branched or cyclic C₁-C₃₀ divalent hydrocarbon group optionally including a heteroatom; or any combination thereof, a21 to a23 may each independently be an integer from 1 to 6;
R₂₁ and R₂₂ may each independently be a hydrogen, a deuterium, a halogen atom, a hydroxyl group, a cyano group, a nitro group, or a linear, branched or cyclic C₁-C₃₀ monovalent hydrocarbon group optionally including a heteroatom, b21 may be an integer from 1 to 4,
b22 may be an integer from 1 to 5,
X₂₁ may be a substituted or unsubstituted C₁-C₃₀ alkyl group, a substituted or unsubstituted C₁-C₃₀ haloalkyl group, a substituted or unsubstituted C₂-C₃₀ alkenyl group, or a substituted or unsubstituted C₆-C₃₀ aryl group,
o may be an integer from 1 to 10,
p may be an integer from 1 to 10,
q may be an integer from 0 to 10, and
adjacent two of A₂₁, L₂₁ to L₂₃, R₂₁, and R₂₂ may optionally be combined with each other to form a ring.

For example, L₁ may be a single bond, a linear or branched C₁-C₃₀ divalent hydrocarbon group, or a cyclic C₃-C₃₀ divalent hydrocarbon group.

For example, X₁ and X₁₄ may each independently be a hydrogen, deuterium, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom.

For example, L₂₁ to L₂₃ may each independently include a single bond; O; S; CO; CO₂; a hydroxyl group; a cyano group; a nitro group; a linear or branched C₁-C₃₀ divalent hydrocarbon group; a linear or branched C₁-C₃₀ divalent hydrocarbon group including a heteroatom; a cyclic C₃-C₃₀ divalent hydrocarbon group; a cyclic C₃-C₃₀ divalent hydrocarbon group including a heteroatom; a linear or branched C₁-C₃₁ monovalent hydrocarbon group; a linear or branched C₁-C₃₁ monovalent hydrocarbon group including a heteroatom; a cyclic C₃-C₃₁ monovalent hydrocarbon group; a cyclic C₃-C₃₁ monovalent hydrocarbon group including a heteroatom; or any combination thereof.

For example, R₂₁ and R₂₂ may each independently be a hydrogen, a deuterium, a halogen atom, a hydroxyl group, a cyano group, a nitro group, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom.

For example, A₂₁, L₂₁ to L₂₃, R₂₁, and R₂₂ may each be independently present, or adjacent two of A₂₁, L₂₁ to L₂₃, R₂₁, and R₂₂ may be combined with each other to form a ring.

The molecular weight of the organometallic compound may be 3000 g/mol or less. Specifically, the molecular weight of the organometallic compound may be 2000 g/mol or less.

Although not limited to a specific theory, radicals may be formed in the organometallic compound by heat and/or high-energy rays. Specifically, a radical may be formed from the M₁₁-carbon bond of the organometallic compound, and optionally, in an atmosphere where water is present, the radical may react to form a chemical bond between the organometallic compounds. Accordingly, the physical properties of the organometallic compound, particularly its solubility in the developer, may change.

Additionally, because the organometallic compound has a ligand of a specific structure, it may have improved photosensitivity, stability, and/or coating properties.

For example, in Formula 1, M₁₁ may be In, Sn, or Sb. Specifically, in Formula 1, M₁₁ may be Sn.

In Formula 1, m may represent the valency of M₁₁.

For example, in Formula 1, n may be an integer from 1 to 4.

For example, in Formula 1, m may be an integer from 0 to 3.

In some example embodiments, in Formula 1, n may be an integer from 1 to 4, m may be an integer from 0 to 3, and M₁₁ may be Sn.

For example, in Formula 1, L₁ may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, substituted or unsubstituted C₂-C₃₀ alkenylene group, substituted or unsubstituted C₃-C₃₀ cycloalkenylene group, substituted or unsubstituted C₃-C₃₀ heterocycloalkenylene group, substituted or unsubstituted C₆-C₃₀ arylene group, or a substituted or unsubstituted C₁-C₃₀ heteroarylene group.

Specifically, in Formula 1, L₁ may be selected from a single bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with a deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof; and/or any combination thereof.

More specifically, in Formula 1, L₁ may be selected from a single bond; and a C₁-C₃₀ alkylene group unsubstituted or substituted with a deuterium, a halogen atom, a hydroxy group, a cyano group, a C₁-C₂₀ alkyl group, a C₁-C₂₀ halogenated alkyl group, or any combination thereof.

For example, in Formula 1, a1 may be an integer of 1 or 2.

For example, in Formula 1, R₁ may be selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, C₁-C₃₀ heteroaryl group and C₂-C₃₀ heteroarylalkyl group, each unsubstituted or substituted with a deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

Specifically, in Formula 1, R₁ may be a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with a deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, R₁ may be selected from any one of the following Formulae 3-1 to 3-15:

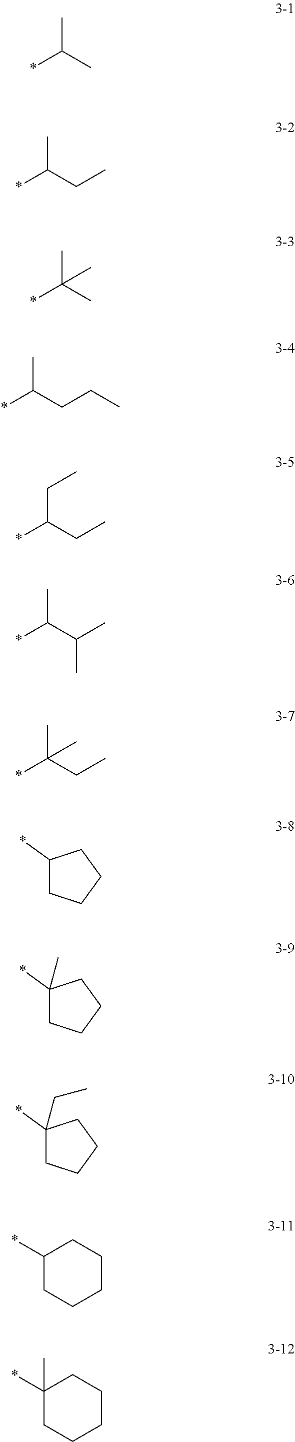

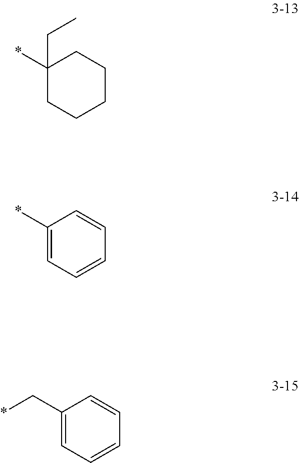

wherein, in Formulae 3-1 to 3-15,
* is a bonding site with a neighboring atom of Formula 1, and
at least one hydrogen may be optionally substituted with a deuterium, a halogen atom, a cyano group, a nitro group, a hydroxy group, a thiol group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, or any combination thereof.

In Formula 1, b1 refers to the number of substitutions for R₁, for example, in Formula 1, b1 may be 1 or 2.

For example, in Formula 1, Y₁ may be O, O(C═O), S, or S(C═O).

For example, in Formula 1, X₁ and X₁₄ may each independently be selected from a hydrogen; a deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group and a C₂-C₃₀ heteroarylalkyl group, each unsubstituted or substituted with a deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

Specifically, in Formula 1, X₁ and X₁₄ may each independently be selected from a hydrogen; a deuterium; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group and a C₂-C₃₀ heteroarylalkyl group, each unsubstituted or substituted with a deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or any combination thereof.

More specifically, in Formula 1, X₁ and X₁₄ may each independently be selected from a hydrogen; a deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, and a C₆-C₃₀ aryl group, each unsubstituted or substituted with a deuterium, a halogen, or any combination thereof.

In particular, in Formula 1, X₁ and X₁₄ may each independently be selected from a hydrogen; a deuterium; and a methyl group, an ethyl group, a n-propyl group, an iso-propyl group, a n-butyl group, a sec-butyl group, an iso-butyl group, a tert-butyl group, a cyclopentyl group, a cyclohexyl group, an ethenyl group, a cyclopentenyl group, a cyclopentadienyl group, a cyclohexenyl group, a cyclohexadienyl group, an ethynyl group, a phenyl group and a naphthyl group, each unsubstituted or substituted with a deuterium, a halogen atom, a methyl group, an ethyl group, a phenyl group, a naphthyl group or any combination thereof.

In some example embodiments, the organometallic compound may be represented by any one of the following Formulae 1-1 to 1-4:

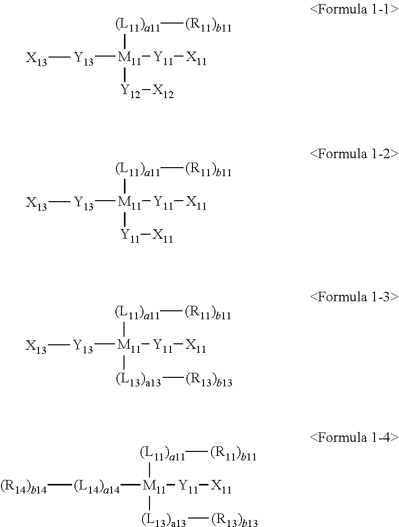

wherein, in Formulae 1-1 to 1-4,
M₁₁ may be the same as defined in Formula 1 (for example, M₁₁ may be indium (In), tin (Sn), antimony (Sb), tellurium (Te), thallium (Tl), lead (Pb), bismuth (Bi), or polonium (Po)),
L₁₁ to L₁₄ may each independently refer to the description of L₁ in Formula 1 (e.g., L₁₁ to L₁₄ may each independently be a single bond or a linear, branched or cyclic C₁-C₃₀ divalent hydrocarbon group, a1 may be an integer from 1 to 4),
a11 to a14 may each independently refer to the description of a1 in Formula 1 (e.g., a11 to a14 may each independently be an integer of 1 or 2), R₁₁ to R₁₄ each independently refer to the description of R₁ in Formula 1 (e.g., R₁₁ to R₁₄ may each independently be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, substituted or unsubstituted C₃-C₃₀ heterocycloalkenyl group, substituted or unsubstituted C₂-C₃₀ alkynyl group, substituted or unsubstituted C₆-C₃₀ aryl group, substituted or unsubstituted C₇-C₃₀ arylalkyl group, a substituted or unsubstituted C₁-C₃₀ heteroaryl group, or a substituted or unsubstituted C₂-C₃₀ heteroarylalkyl group),
b11 to b14 may each independently refer to the description of b1 in Formula 1 (e.g., b11 to b14 may each independently be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, substituted or unsubstituted C₃-C₃₀ heterocycloalkenyl group, substituted or unsubstituted C₂-C₃₀ alkynyl group, substituted or unsubstituted C₆-C₃₀ aryl group, substituted or unsubstituted C₇-C₃₀ arylalkyl group, a substituted or unsubstituted C₁-C₃₀ heteroaryl group, or a substituted or unsubstituted C₂-C₃₀ heteroarylalkyl group, and adjacent two of the plurality of R₁ may be optionally combined with each other to form a condensed ring)
Y₁₁ to Y₁₃ may each independently refer to the description of Y₁ in Formula 1 (e.g., Y₁₁ to Y₁₃ may each independently be O, O(C═O), S, S(C═O), NX₁₄ or N(C═O)), and
X₁₁ to X₁₄ may each independently refer to the description of X₁ in Formula 1 (e.g., X₁₁ to X₁₄ may each independently be hydrogen, deuterium, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom).

In some example embodiments, the organometallic compound may be represented by any one of Formulae 1-1 to 1-3.

In some example embodiments, the organometallic compound represented by Formula 1 may be selected from the following Group I:

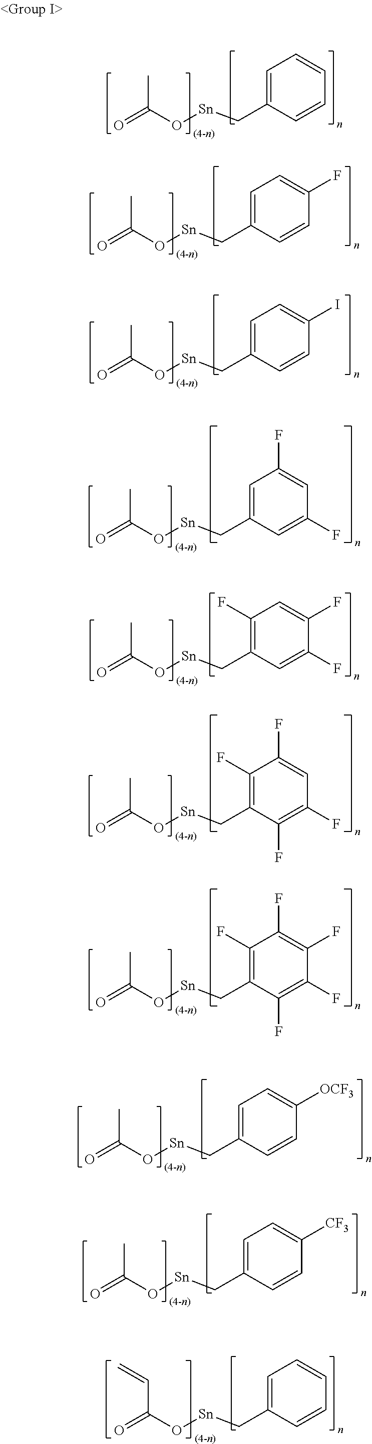

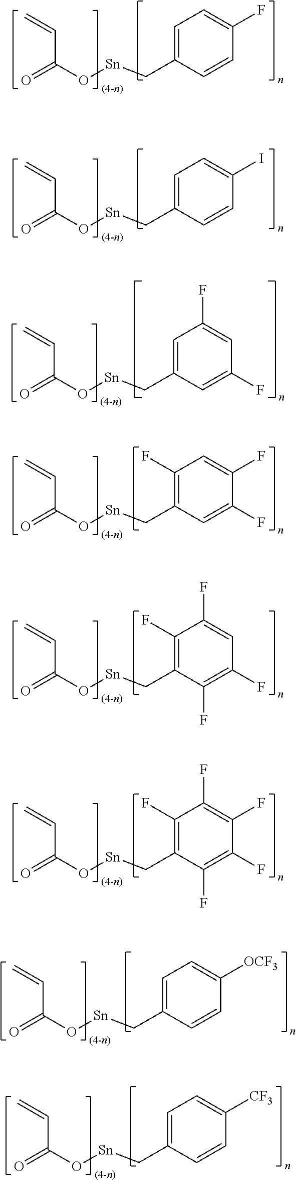

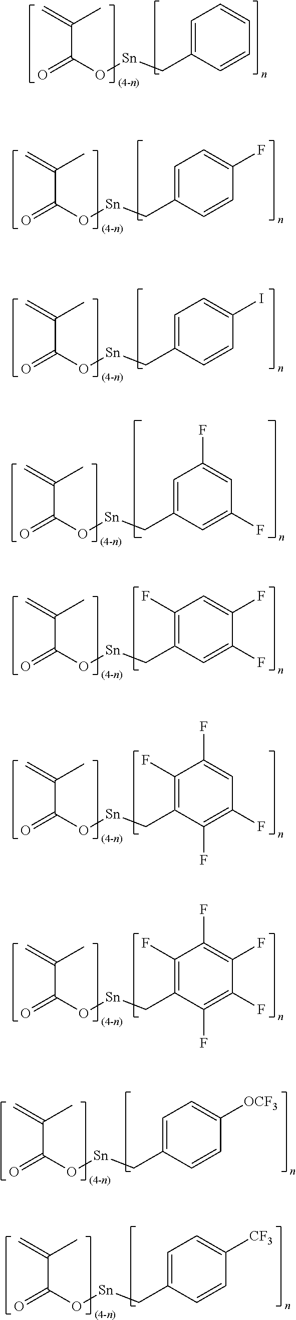

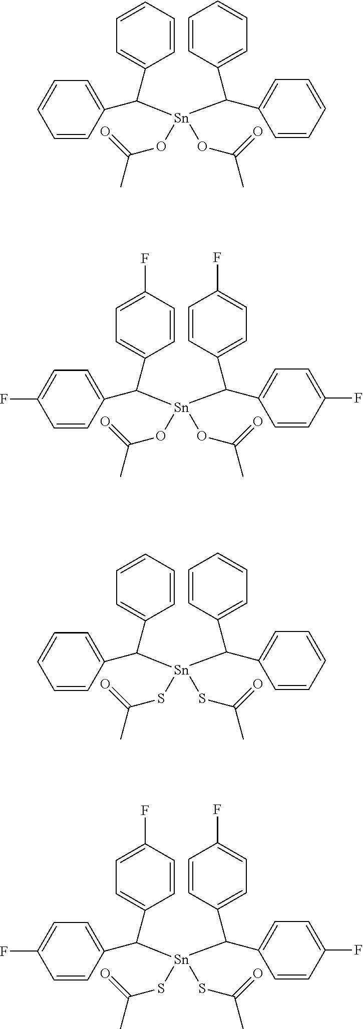 [SMILES: CC(=O)[O][Sn]([O]C(C)=O)([CH](c1ccccc1)c1ccccc1)[CH](c1ccccc1)c1ccccc1 ; CC(=O)[O][Sn]([O]C(C)=O)([CH](c1ccc(F)cc1)c1ccc(F)cc1)[CH](c1ccc(F)cc1)c1ccc(F)cc1 ; CC(=O)[S][Sn]([S]C(C)=O)([CH](c1ccccc1)c1ccccc1)[CH](c1ccccc1)c1ccccc1 ; CC(=O)[S][Sn]([S]C(C)=O)([CH](c1ccc(F)cc1)c1ccc(F)cc1)[CH](c1ccc(F)cc1)c1ccc(F)cc1]

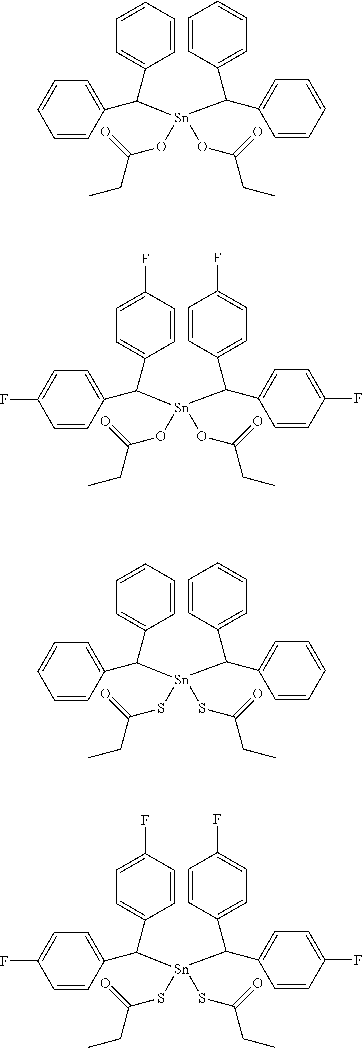 [SMILES: CCC(=O)[O][Sn]([O]C(=O)CC)([CH](c1ccccc1)c1ccccc1)[CH](c1ccccc1)c1ccccc1 ; CCC(=O)[O][Sn]([O]C(=O)CC)([CH](c1ccc(F)cc1)c1ccc(F)cc1)[CH](c1ccc(F)cc1)c1ccc(F)cc1 ; CCC(=O)[S][Sn]([S]C(=O)CC)([CH](c1ccccc1)c1ccccc1)[CH](c1ccccc1)c1ccccc1 ; CCC(=O)[S][Sn]([S]C(=O)CC)([CH](c1ccc(F)cc1)c1ccc(F)cc1)[CH](c1ccc(F)cc1)c1ccc(F)cc1]

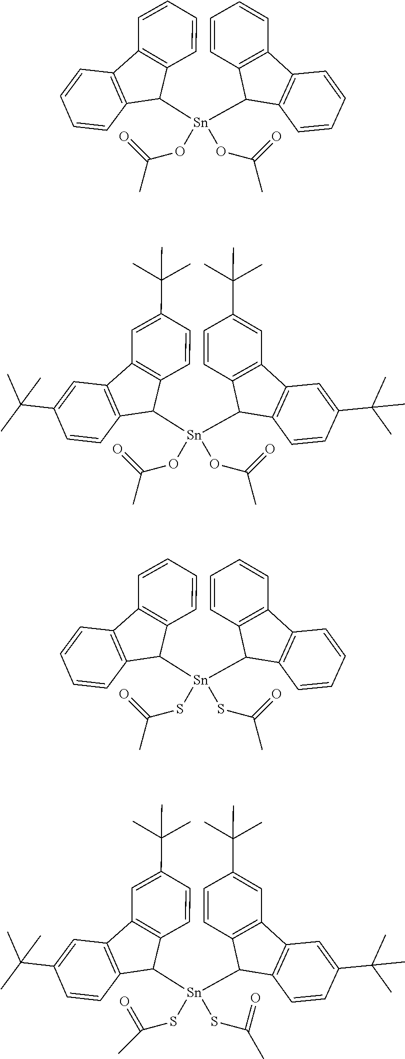

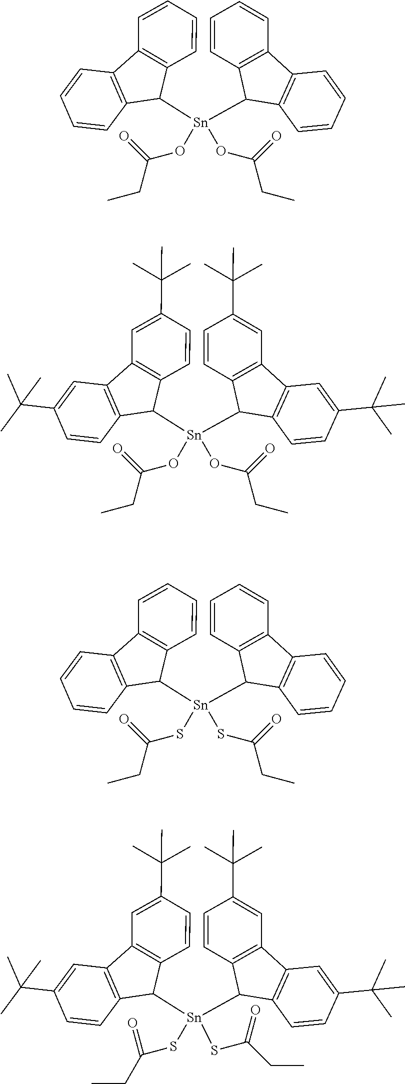

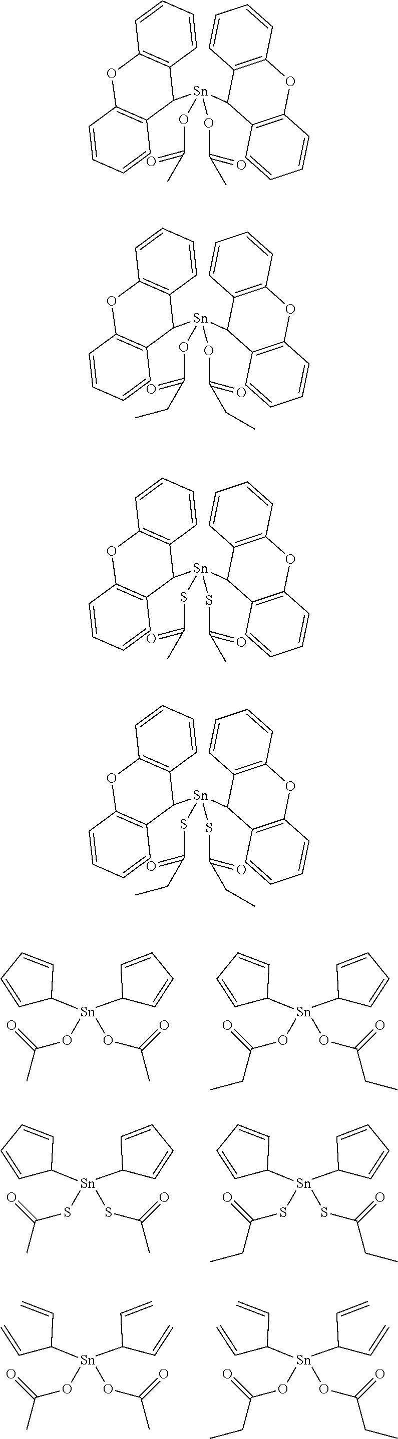

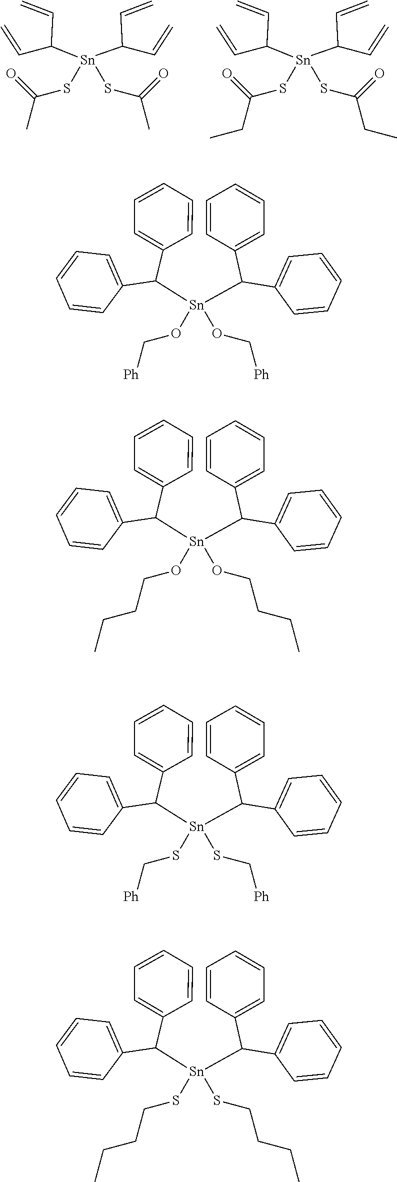

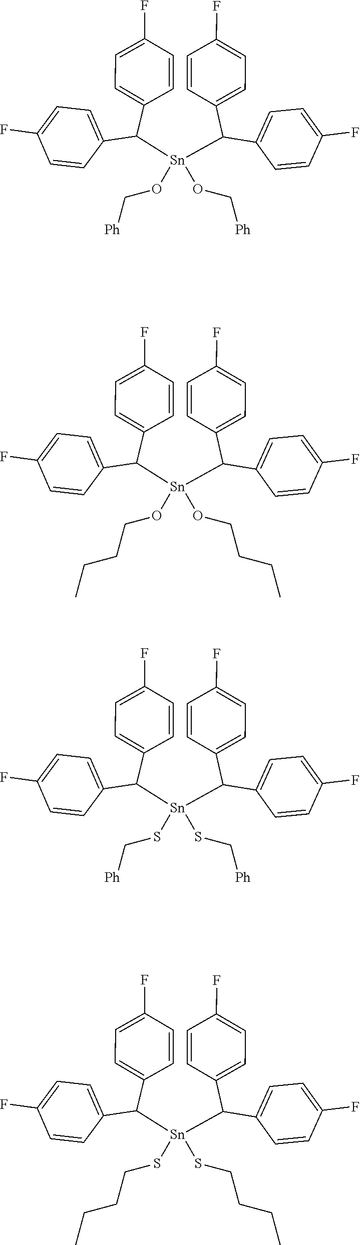 [SMILES: Fc1ccc([CH](c2ccc(F)cc2)[Sn]([O]Cc2ccccc2)([O]Cc2ccccc2)[CH](c2ccc(F)cc2)c2ccc(F)cc2)cc1 ; CCCC[O][Sn]([O]CCCC)([CH](c1ccc(F)cc1)c1ccc(F)cc1)[CH](c1ccc(F)cc1)c1ccc(F)cc1 ; Fc1ccc([CH](c2ccc(F)cc2)[Sn]([S]Cc2ccccc2)([S]Cc2ccccc2)[CH](c2ccc(F)cc2)c2ccc(F)cc2)cc1 ; CCCC[S][Sn]([S]CCCC)([CH](c1ccc(F)cc1)c1ccc(F)cc1)[CH](c1ccc(F)cc1)c1ccc(F)cc1]

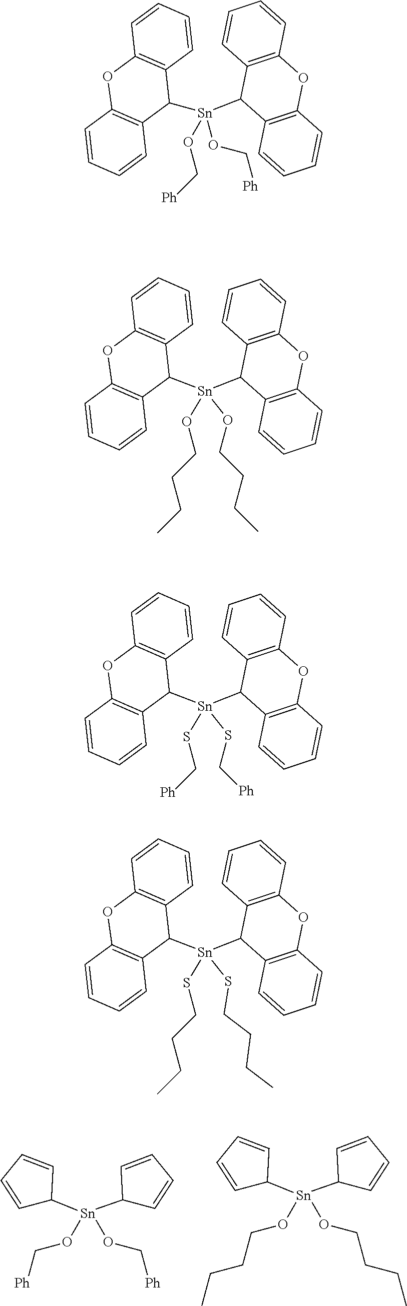 [SMILES: c1ccc(C[O][Sn]([O]Cc2ccccc2)([CH]2c3ccccc3Oc3ccccc32)[CH]2c3ccccc3Oc3ccccc32)cc1 ; CCCC[O][Sn]([O]CCCC)([CH]1c2ccccc2Oc2ccccc21)[CH]1c2ccccc2Oc2ccccc21 ; c1ccc(C[S][Sn]([S]Cc2ccccc2)([CH]2c3ccccc3Oc3ccccc32)[CH]2c3ccccc3Oc3ccccc32)cc1 ; CCCC[S][Sn]([S]CCCC)([CH]1c2ccccc2Oc2ccccc21)[CH]1c2ccccc2Oc2ccccc21 ; C1=C[CH]([Sn]([O]Cc2ccccc2)([O]Cc2ccccc2)[CH]2C=CC=C2)C=C1 ; CCCC[O][Sn]([O]CCCC)([CH]1C=CC=C1)[CH]1C=CC=C1]

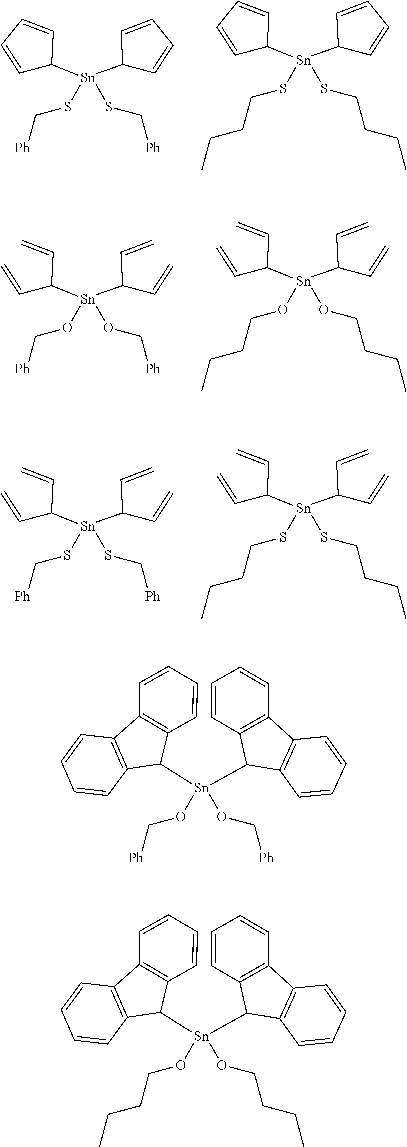

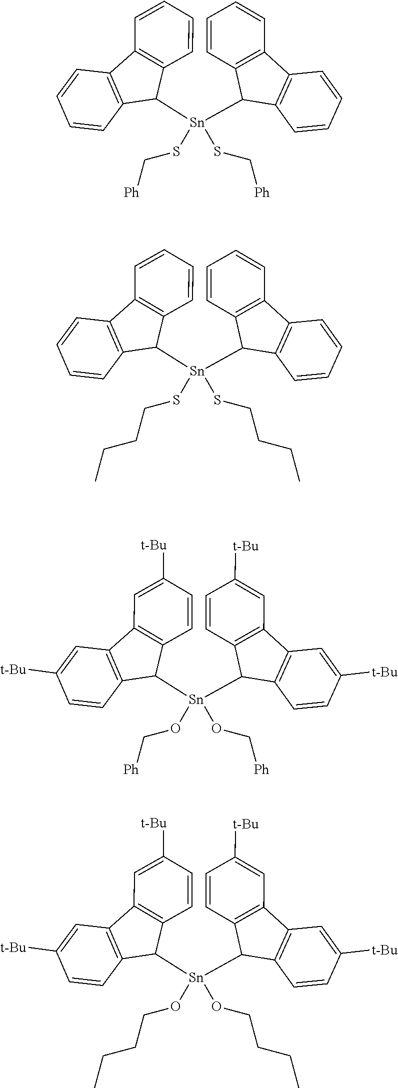 [SMILES: c1ccc(C[S][Sn]([S]Cc2ccccc2)([CH]2c3ccccc3-c3ccccc32)[CH]2c3ccccc3-c3ccccc32)cc1 ; CCCC[S][Sn]([S]CCCC)([CH]1c2ccccc2-c2ccccc21)[CH]1c2ccccc2-c2ccccc21 ; CC(C)(C)c1ccc2c(c1)-c1cc(C(C)(C)C)ccc1[CH]2[Sn]([O]Cc1ccccc1)([O]Cc1ccccc1)[CH]1c2ccc(C(C)(C)C)cc2-c2cc(C(C)(C)C)ccc21 ; CCCC[O][Sn]([O]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21]

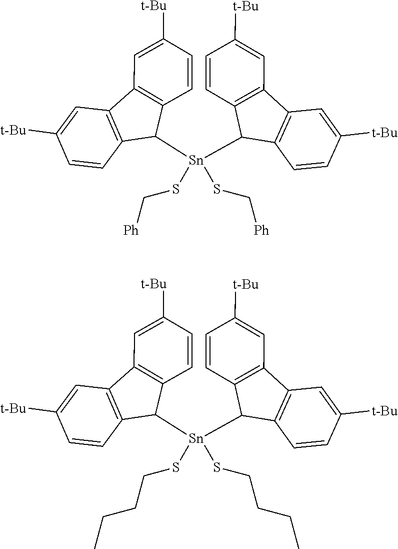 [SMILES: CC(C)(C)c1ccc2c(c1)-c1cc(C(C)(C)C)ccc1[CH]2[Sn]([S]Cc1ccccc1)([S]Cc1ccccc1)[CH]1c2ccc(C(C)(C)C)cc2-c2cc(C(C)(C)C)ccc21 ; CCCC[S][Sn]([S]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21]

wherein in Group I, n is an integer from 1 to 4.

For example, in Formula 2, A₂₁ may be selected from a single bond, a substituted or unsubstituted carbon atom, and/or a (p+q)-valent bonding unit including at least one of a substituted or unsubstituted carbon atom and a substituted or unsubstituted benzene as a repeating unit.

Specifically, in Formula 2, A₂₁ may be selected from a single bond, a substituted or unsubstituted carbon atom, and/or a (p+q)-valent bonding unit represented by any one of the following Formulae 4-1 to 4-21:

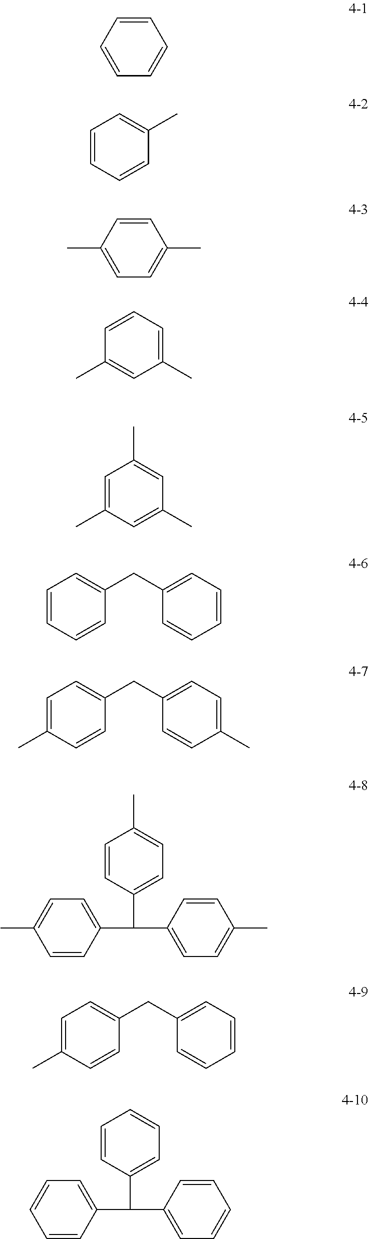

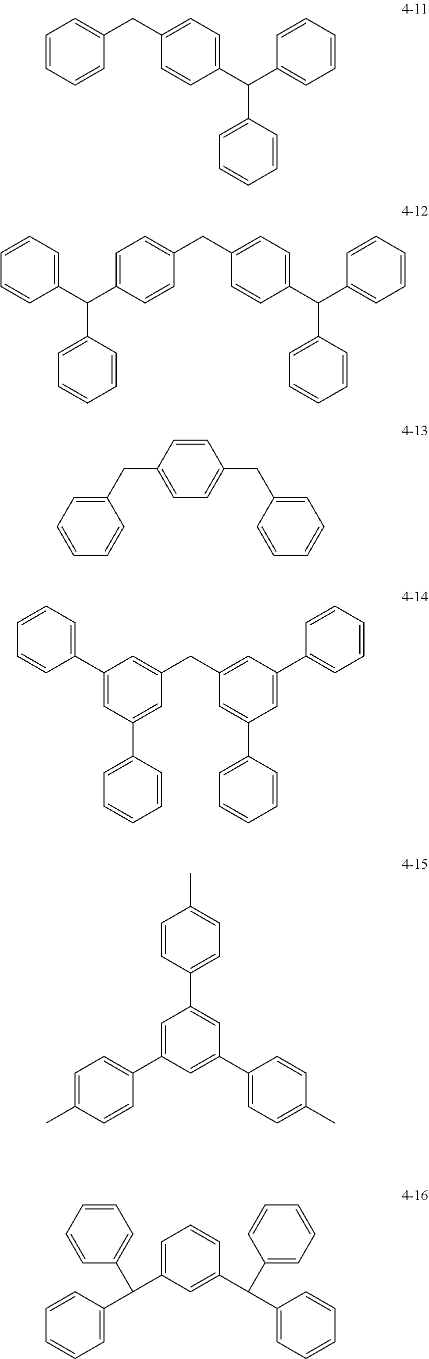

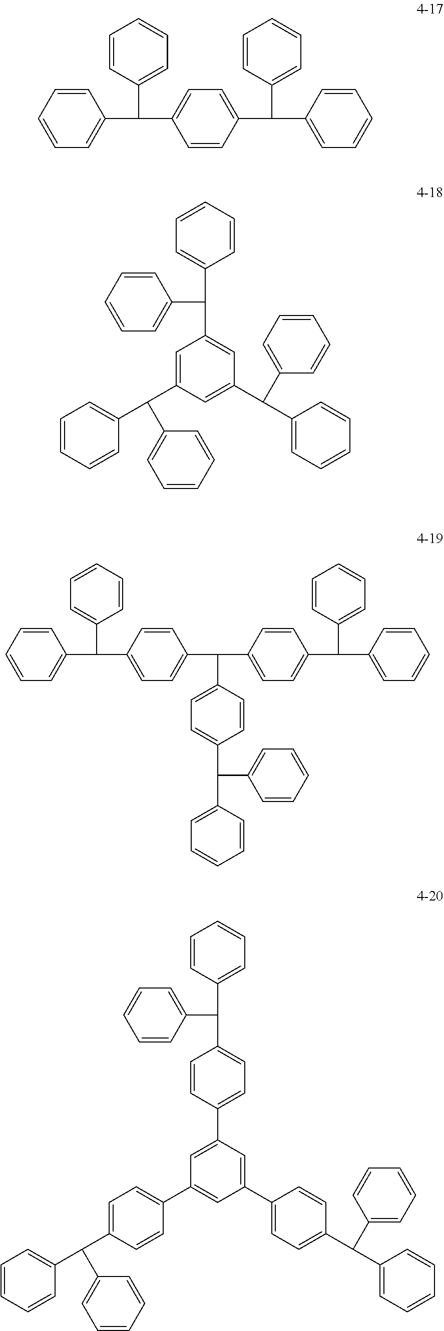

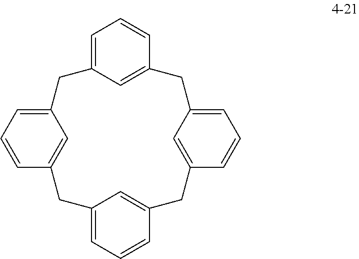 [SMILES: c1cc2cc(c1)Cc1cccc(c1)Cc1cccc(c1)Cc1cccc(c1)C2]

wherein in Formulae 4-1 to 4-21,
any hydrogen may be optionally (e.g. independently) substituted with either of the following p or q groups,

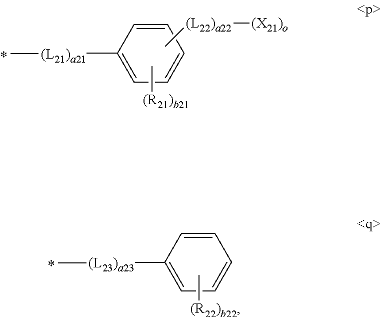

* being a bonding site with a neighboring atom of Formula 2 and L₂₁ to L₂₃, a21 to a23, R₂₁, R₂₂, b21, b22, X₂₁, and o being the same as defined with regard to Formula 2, and/or any substituent.

More specifically, in Formula 2, A₂₁ may be selected from Formula 4-8.

For example, more specifically with regard to Formula 2, L₂₁ to L₂₃ may each independently be a single bond, O, S, CO, CO₂, CRₐR_{b}, or any combination thereof.

Ra and Rb may each independently be a hydrogen, a deuterium, a halogen atom, a hydroxyl group, a cyano group, a nitro group, or a linear, branched or cyclic C₁-C₁ monovalent hydrocarbon group optionally including a heteroatom.

Additionally, in Formula 2, L₂₁ to L₂₃ may each independently be a single bond, O, CO, CO₂, CRₐR_{b}, or any combination thereof.

Rₐ and R_{b} may each independently be a hydrogen, a deuterium, F, or a linear or branched C₁-C₁₀ monovalent hydrocarbon group optionally including F.

For example, in Formula 2, R₂₁ and R₂₂ may each independently be a hydrogen, a deuterium, a halogen atom, a hydroxyl group, a cyano group, a nitro group, a substituted or unsubstituted C₁-C₃₀ alkyl group, a substituted or unsubstituted C₃-C₃₀ cycloalkyl group, a substituted or unsubstituted C₂-C₃₀ alkenyl group, a substituted or unsubstituted C₃-C₃₀ cycloalkenyl group, a substituted or unsubstituted C₂-C₃₀ alkynyl group, or a substituted or unsubstituted C₆-C₃₀ aryl group.

Specifically, in Formula 2, R₂₁ and R₂₂ may each independently be selected from a hydrogen, a deuterium, a halogen atom, a hydroxyl group, a cyano group, a nitro group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group and a C₆-C₃₀ aryl group, each unsubstituted or substituted with a deuterium, a halogen atom, a hydroxyl group, a cyano group, a nitro group, an amino group, a carbonyl group, a carboxylate group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ halogenated alkoxy group, a C₃-C₂₀ cycloalkyl group, a C₃-C₂₀ cycloalkoxy group, a C₂-C₂₀ alkenyl group, a C₆-C₂₀ aryl group, or any combination thereof.

For example, in Formula 2, X₂₁ may be selected from a substituted or unsubstituted C₁-C₁₀ haloalkyl group, a substituted or unsubstituted vinyl group, or a group represented by the following Formula 5-1:

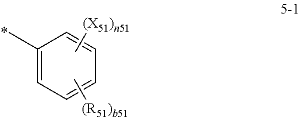

wherein in Formula 5-1,
X₅₁ is a halogen atom, a substituted or unsubstituted C₁-C₁₀ haloalkyl group, or a substituted or unsubstituted vinyl group,
n51 is an integer from 1 to 5,
R₅₁ is a hydrogen, a deuterium, a halogen atom, a hydroxyl group, a substituted or unsubstituted C₁-C₁₀ haloalkyl group, or a substituted or unsubstituted vinyl group,
b51 is an integer from 0 to 4, and
* is a bonding site with a neighboring atom of Formula 2.

Specifically, in Formula 2, X₂₁ may be represented by the following Formula 5-11:

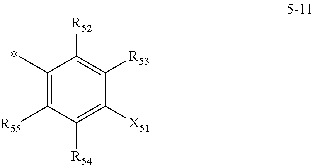

wherein in Formula 5-11,
X₅₁ is F, a C₁-C₁₀ alkyl group substituted with F, or a vinyl group,
R₅₁ is hydrogen, F, or a C₁-C₁₀ alkyl group substituted with F, and
* is a bonding site with a neighboring atom.

In some example embodiments, the additive represented by Formula 2 may be represented by Formula 2-1:

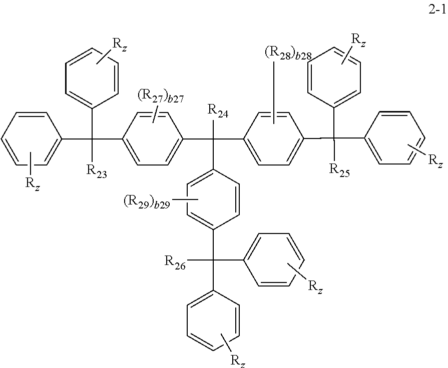

wherein in Formula 2-1,
R_{z} is selected from R₂₂ and (L₂₂)ₐ₂₂-(X₂₁)ₒ, at least one of R_{z} is (L₂₂)ₐ₂₂-(X₂₁)ₒ,
R₂₂ to R₂₉ are each independently the same as the definition of R₂₂ in Formula 2 above,
b27 to b29 each independently are an integer of 1 to 4.

For example, in Formula 2-1, R_{z} may be (L₂₂)ₐ₂₂-(X₂₁)ₒ.

In some example embodiments, the additive represented by Formula 2 may be selected from the following Group II:

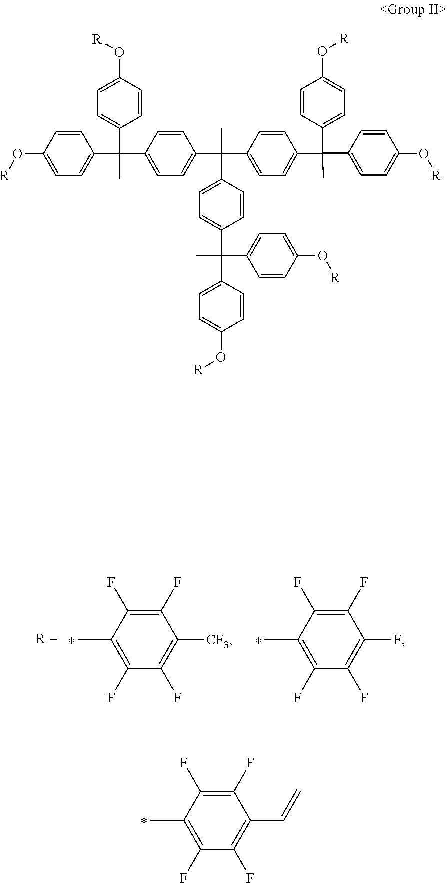

Wherein in Group II,
* is a bonding site with a neighboring atom, and
the R groups may each independently selected from one of the depicted groups. For example, each R may be independently one of

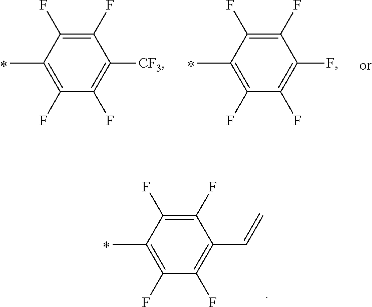

The additive may react with radicals generated from the organometallic compound to form a crosslink. Accordingly, a resist composition including the additive may have improved light sensitivity, stability and/or coating properties compared to a resist composition without the additive.

In particular, a resist composition including the additives may have an appropriate shelf life for commercial distribution.

The organometallic compound may be any one compound represented by Formula 1, or a mixture of two or more compounds may be used.

Likewise, the additive may be any one compound represented by Formula 2, or a mixture of two or more compounds may be used.

In the resist composition, the organometallic compound may be about 0.01 parts by weight to about 100 parts by weight, specifically, 0.2 or more, 0.5 or more, 1 or more, 1.5 or more, 90 or less, or 80 or less parts by weight, based on 100 parts by weight of the resist composition. If the above-mentioned range is satisfied, chemical bonds between organometallic compounds are sufficiently formed and side reactions are suppressed or reduced, thereby providing a resist composition with improved sensitivity and/or resolution.

In the resist composition, the additive may be about 0.01 parts by weight to about 100 parts by weight, specifically, 0.2 or more, 0.5 or more, 1 or more, 1.5 or more, 90 or less, or 80 or less parts by weight, based on 100 parts by weight of the resist composition. If the above-mentioned range is satisfied, a resist composition with improved sensitivity and/or resolution may be provided by sufficiently forming chemical bonds between organometallic compounds while suppressing side reactions, and improving the solubility of the organometallic compounds.

In the resist composition, the additive may be included in an amount of about 0.1 parts by weight to about 100,000 parts by weight based on 100 parts by weight of the organometallic compound. Specifically, the additive may be included in an amount of about 5 parts by weight to about 100 parts by weight, more specifically, about 10 parts by weight to about 20 parts by weight, based on 100 parts by weight of the organometallic compound. If the above-mentioned range is satisfied, the photosensitivity, stability, and/or coating properties of the resist composition may be improved.

The solubility of the resist composition with respect to the developer changes by exposure to high-energy rays. The resist composition may be a negative resist composition in which a non-exposed portions of the resist film is dissolved and removed to form a negative resist pattern.

In addition, the resist composition according to some example embodiments may be for an alkaline developing process using an alkaline developer for developing treatment when forming a resist pattern, or for a solvent developing process using a developer including an organic solvent for the developing treatment (hereinafter, also referred to as an organic developer).

Since the resist composition is a non-chemically amplified type, it may not substantially include a photoacid generator.

Since the physical properties of the organometallic compound change upon exposure to light, the resist composition may not substantially include compounds with a molecular weight of 1,000 or more other than the organometallic compound and the additive.

The organometallic compound and the additive may be prepared by any appropriate method, or commercially available products may be used.

The structure (composition) of the organometallic compound may be identified through Fourier transform infrared (FT-IR) analysis, NMR analysis, X-ray fluorescence (XRF) analysis, mass spectrometry, ultra violate (UV) analysis, single crystal X-ray structure analysis, powder X-ray diffraction (PXRD) analysis, liquid chromatography (LC), size exclusion chromatography (SEC) analysis, thermal analysis, etc. A detailed confirmation method is as described in Examples below.

### <Organic Solvent>

The resist composition may further include an organic solvent.

The organic solvent included in the resist composition is not particularly limited, as long as the organometallic compound and the additive and any component included therein as needed may be dissolved or dispersed therein. As the organic solvent, one type of an organic solvent may be used, or two or more different types of organic solvents may be used in combination.

In some example embodiments, the organic solvent may include a protic organic solvent, an aprotic organic solvent, or any combination thereof.

In some example embodiments, the organic solvent may be a mixture including an aprotic organic solvent and a protic organic solvent.

Since the resist composition may be substantially free of water, the organic solvent may not include water. Specifically, the resist composition may include not more than 3 wt % water, and the organic solvent may include not more than 3 wt % water.

Examples of the organic solvent are an alcohol-based solvent, an ether-based solvent, a ketone-based solvent, an amide-based solvent, an ester-based solvent, a sulfoxide-based solvent, a hydrocarbon-based solvent, and/or the like.

More specifically, examples of the alcohol-based solvent are: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexane alcohol, 3,3,5-trimethylcyclohexanol, benzyl alcohol, diacetone alcohol, and the like; a polyhydric alcohol solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-including ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and/or the like.

Examples of the ether-based solvent include dialkyl ether-based solvents such as diethyl ether, dipropyl ether, dibutyl ether, diethylene glycol dimethyl ether, dipropylene glycol dimethyl ether, cyclic ether solvents such as tetrahydrofuran and tetrahydropyran, and aromatic ring-including ether-based solvents such as diphenyl ether and/or anisole.

Examples of the ketone-based solvent are a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone, a cyclic ketone-based solvent such as cyclopentanone, cyclohexanone, cycloheptanone, cyclooctanone, or methylcyclohexanone; 2,4-pentanedione, acetonyl acetone, and/or acetophenone.

Examples of the amide-based solvent are a cyclic amide-based solvent such as N,N′-dimethylimidazolidinone or N-methyl-2-pyrrolidone; and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent are: an acetate ester-based solvent, such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyhydric alcohol-including ether carboxylate-based solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA) propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; a lactone solvent, such as γ-butyrolactone and δ-valerolactone; a carbonate-based solvent, such as dimethyl carbonate, diethyl carbonate, ethylene carbonate, and propylene carbonate; and a lactate ester-based solvent, such as methyl lactate, ethyl lactate, n-butyl lactate, and n-amyl lactate; glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and/or diethyl phthalate.

Examples of the sulfoxide-based solvent are dimethyl sulfoxide and/or diethyl sulfoxide.

Examples of the hydrocarbon-based solvent are an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane, and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the organic solvent may be selected from alcohol-based solvents, ketone-based solvents, ester-based solvents, and a combinations thereof. More specifically, the organic solvent may be selected from 4-methyl-2-pentaneol (MIBC), propylene glycol monomethyl ether, propylene glycol monoethyl ether, propylene glycol monomethyl ether acetate, ethyl lactate, cyclohexanone, and/or any combination thereof.

The organic solvent may be used in an amount of about 0 parts by weight to about 99.9 parts by weight based on 100 parts by weight of the resist composition. The organic solvent may be used alone or any mixture of two or more different surfactants may also be used.

### <Any Components>

The resist composition may further include a surfactant, a crosslinking agent, a leveling agent, a colorant, or any combination thereof as necessary.

The resist composition may further include a surfactant to improve coatability, developability, and the like. Example of the surfactant are a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant are KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and/or Surflon™ SC-106 (manufactured by AGC Seimi Chemical Co., Ltd.).

The surfactant may be included in a range of about 0 parts by weight to about 20 parts by weight based on 100 parts by weight of the resist composition. As the surfactant, one type of a surfactant may be used, or two or more different types of surfactants may be mixed and used.

A method of preparing the resist composition is not particularly limited, and the resist composition may be prepared by, for example, mixing the organometallic compound and optional components added as needed. A temperature or time during mixing is not particularly limited. If necessary, filtration may be performed after mixing.

### [Pattern Formation Method]

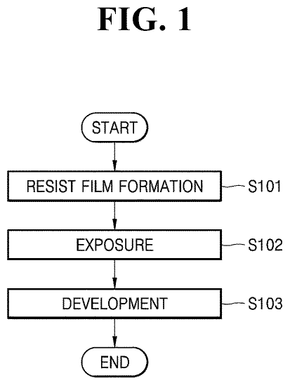

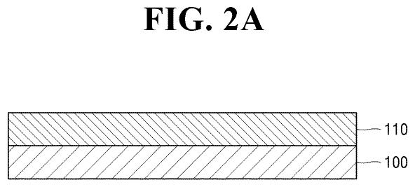

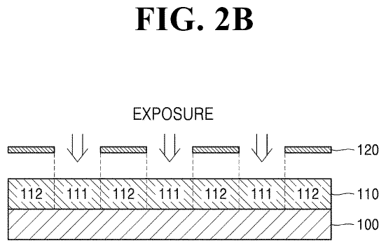

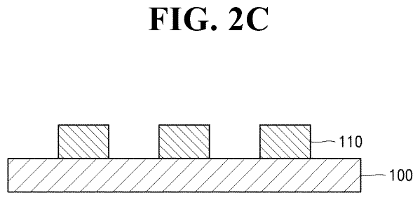

Hereinafter, a pattern formation method according to some example embodiments will be described in more detail with reference to FIGS. 1 and 2A to 2C. FIG. 1 is a flowchart representing a pattern formation method according to some example embodiments, and FIGS. 2A to 2C are each a side cross-sectional view illustrating a pattern formation method according to some example embodiments. Hereinafter, a pattern formation method using a negative resist composition will be described by way of example, but the example embodiments are not limited thereto.

Referring to FIG. 1, the pattern formation method may include operation S101 of applying a resist composition to form a resist film, operation S102 of exposing at least a portion of the resist film to high energy rays, and operation S103 of developing the exposed resist film using a developer. Such operations may be omitted if necessary, or may be performed in a different order.

First, a substrate 100 may be prepared. The substrate 100 may include, for example, a semiconductor substrate such as a silicon substrate or a germanium substrate, glass, quartz, ceramic, or copper. In some example embodiments, the substrate 100 may include a Group Ill-Group V compound such as GaP, GaAs, GaSb, or the like.

Referring to FIG. 2A, a resist composition may be applied to a desired thickness on the substrate 100 by, for example, coating, to form a resist film 110. If necessary, the resist film 110 may be heated (pre-baked, PAB) to remove the organic solvent remaining therein. Alternatively, by heating the resist film 110, radicals may be generated, and then through exposure, the radicals may chemically combine to form a crosslink.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nm to about 300 nm. More specifically, the resist film 110 may have a thickness of about 30 nm to about 200 nm.

The lower limit of the temperature of PB may be 60° C. or more, specifically 80° C. or more. Additionally, the upper limit of the temperature of PB may be 150° C. or less, specifically 140° C. or less. The lower limit of the time of PB may be 5 seconds or more, specifically 10 seconds or more. The upper limit of the prebake time may be 600 seconds or less, specifically 300 seconds or less.

Before the applying of the resist composition on the substrate 100, an etching target film (not shown) may be further formed on the substrate 100. The etching target film may refer to a layer on which an image is transferred from a resist pattern and converted into a certain pattern. In some example embodiments, the etching target film may be formed to include, for example, an insulating material such as silicon oxide, silicon nitride, or silicon oxynitride. In some example embodiments, the etching target film may be formed to include a conductive material such as a metal, metal nitride, metal silicide, or metal silicide nitride. In some example embodiments, the etching target film may be formed to include a semiconductor material such as polysilicon.

In some example embodiments, an antireflection film may be further formed on the substrate 100 to increase or maximize the efficiency of a resist. The antireflection film may be an organic or inorganic antireflection film.

In some example embodiments, a protective film may be further provided on the resist film 110 to reduce the influence of alkaline impurities or the like included during a process. When immersion exposure is performed, for example, a protective film for immersion may also be provided on the resist film 100 to avoid or reduce in likelihood contact, for example direct contact, between an immersion medium and the resist film 110.

Next, referring to FIG. 2B, at least a portion of the resist film 110 may be exposed to high energy rays. For example, high energy rays passing through a mask 120 may be irradiated onto at least a portion of the resist film 110. For this reason, the resist film 110 may have an exposed portion 111 and an unexposed portion 112.

Although not limited to a specific theory, radicals are generated in the exposed portion 111 by exposure, and chemical bonds are formed between the radicals, which may change the physical properties of the resist composition.

In some cases, the exposure may be performed by irradiating high energy rays through a mask with a certain pattern using a liquid such as water as a medium. Examples of the high-energy rays may include electromagnetic waves such as ultraviolet rays, deep ultraviolet rays, extreme ultraviolet (EUV) rays (wavelength of 13.5 nm), X-rays, and γ-rays; and/or charged particle beams such as electron beams (EBs) and/or a particle beams. Irradiation of these high-energy rays can be collectively referred to as “exposure.”

Various light sources may be used for the exposure, for example, a light source emitting laser beams in the UV range, such as a KrF excimer laser (wavelength of 248 nm), an ArF excimer laser (wavelength of 193 nm), and/or an F2 excimer laser (wavelength of 157 nm), a light source emitting harmonic laser beams in the far ultraviolet or vacuum ultraviolet range by converting wavelengths of laser beams received from a solid laser light source (YAG or semiconductor laser), and/or a light source emitting EBs or EUVs may be used. During exposure, the exposure may be usually performed through a mask corresponding to a desired pattern, but when exposure light is an EB, the exposure may be performed through direct writing without using a mask.

In the case of using extreme ultraviolet rays as the high-energy rays, an integral dose of the high-energy rays may be 2000 mJ/cm² or less or 500 mJ/cm² or less. In addition, when EBs are used as the high energy rays, the integral dose may be 5,000 μC/cm² or less, or 1,000 μC/cm² or less.

In addition, post-exposure bake (PEB) may be performed after the exposure. The lower limit of the temperature of PEB may be 50° C. or more, specifically 80° C. or more. An upper limit of the PEB temperature may be 250° C. or lower, specifically 200° C. or lower. The lower limit of the time of the PEB time may be 5 seconds or more, specifically 10 seconds or more. The upper limit of the time of the PEB may be 600 seconds or less, specifically 300 seconds or less.

Next, referring to FIG. 2C, the exposed resist film 110 may be developed using a developer. The non-exposed region 112 may be removed by being washed away by the developer, and the exposed portion 111 remains without being washed away by the developer. For example, after applying the developer to the exposed resist film 110, the remaining exposed resist film 110 may be the remainder of the resist film 110 corresponding to the exposed portion 11 that is not removed during the developing process based on the exposure.

Examples of the developer include a developer including an organic solvent (hereinafter also referred to as “organic developer”). Examples of a developing method are a dipping method, a puddle method, a spray method, a dynamic injection method, and the like. A developing temperature may be, for example, about 5° C. or more and about 60° C. or less, and a developing time may be, for example, about 5 seconds or more and about 300 seconds or less.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and/or 1,5-diazabicyclo[4.3.0]-5-nonene (DBN) are dissolved. The alkaline developer may further include a surfactant.

A lower limit of an amount of the alkaline compound included in the alkaline developer may be 0.1 wt % or more or 0.5 wt % or more, or 1 wt % or more. Additionally, an upper limit of the amount of the alkaline compound included in the alkaline developer may be 20 wt % or less, or 10 wt % or less, or 5 wt % or less.

Examples of the organic solvent included in the organic developer may include the same organic solvents as those exemplified in the part of <Organic solvent> of [Resist composition]. Specifically, the organic developer may be n-butyl acetate (nBA), propylene glycol methyl ether (PGME), propylene glycol methyl ether acetate (PGMEA), γ-butyrolactone (GBL), isopropanol (IPA), etc. The organic developer may include more organic acids such as acetic acid, formic acid, citric acid, etc.

Regarding the organic developer, a lower limit of the amount of the organic solvent may be 80 wt % or more, 90 wt % or more, 95 wt % or more, or 99 wt % or more.

The organic developer may also include a surfactant. Additionally, a trace amount of water may be included in the organic developer. In addition, during development, development may be stopped by substituting with a different kind of solvent from the organic developer.

The resist pattern after the development may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate and the resist pattern may be removed. In addition, when the ultrapure water is used, water remaining on the substrate 100 and the resist pattern may be removed.

In addition, developers may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and/or the like.

The resist pattern remaining after the etching may be peeled off with an organic solvent. Examples of such an organic solvent may include, but are not limited to, propylene glycol monomethylether acetate (PGMEA), propylene glycol monomethylether (PGME), ethyl lactate (EL), and/or the like. A peeling method is not particularly limited, but examples thereof may include an immersion method, a spray method, and/or the like. In addition, the interconnection substrate on which the resist pattern is formed may be a multilayer interconnection substrate or may have small-diameter through-holes.

In some example embodiments, the interconnection substrate may be formed through a method of forming a resist pattern, depositing a metal in a vacuum, and then melting the resist pattern with a solution, that is, a lift-off method.

The present inventive concepts will be described in more detail using the following examples and comparative examples, but the technical scope of the present inventive concepts are not limited to the following examples.

### EXAMPLES

### Synthesis Example 1: Synthesis of T1

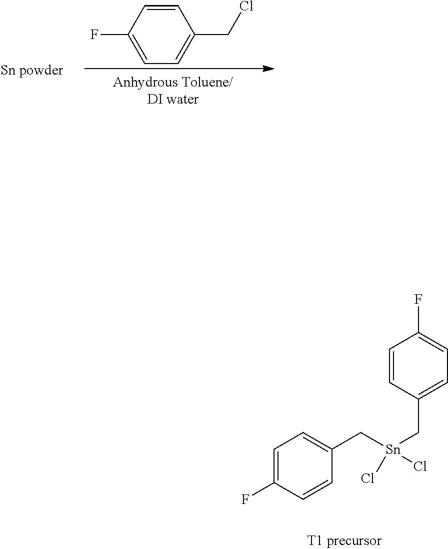 [SMILES: Fc1ccc(CCl)cc1 ; Fc1ccc([CH2][Sn]([Cl])([Cl])[CH2]c2ccc(F)cc2)cc1]

8.2 g (69.2 mmol) of Sn powder and 120 ml of dry toluene were added to a 250 ml three-necked flask, and the temperature was raised to 90° C. About 1.0 ml of DI water was added thereto, and then, 10.0 g (69.2 mmol) of 4-fluorobenzyl chloride was added dropwise during 10 minutes. Heating, refluxing and stirring were performed at 130° C. for 4 hours, and then, unreacted Sn powder was filtered out using a Buchner funnel. At the same time, as the filtered solution was cooled, 6.5 g of white crystals (T1 precursor) as a product (yield of 36%) were obtained.

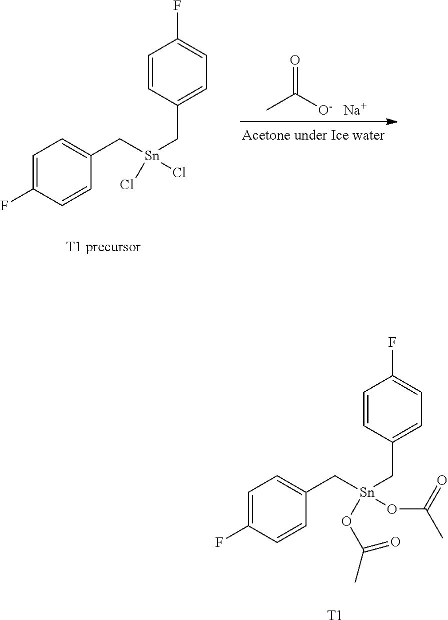

1.5 g (3.7 mmol) of T1 precursor and 21.0 ml of dry acetone were added to a 50 ml single-necked flask, and the temperature was lowered to 0° C. 0.6 g (7.4 mmol) of sodium acetate was added, and then, stirred for about 12 hours. NaCl salt produced in the solution was filtered using a 0.45 μm filter, and the resultant solution was rotary evaporated and dried under vacuum to obtain T1 (1.6 g) with the yield of 74%.

¹H-NMR (500 MHz, DMSO-d₆): δ ˜6.9 (8H), ˜2.6 (4H), ˜1.6 (6H)

### Synthesis Example 2: Synthesis of T2

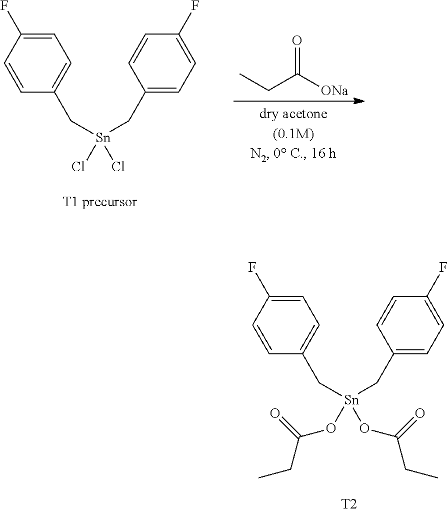

T1 precursor (4.0 g, 9.81 mmol) was added to a round bottom flask and replaced with N₂. After dilution with Acetone (98 ml, 0.1 M), sodium propionate (1.88 g, 19.6 mmol) was added at 0° C. After reacting at 0° C. for 16 hours, it was filtered using celite. After removing the solvent, recrystallization was performed (dichloromethane:n-hexane=10 ml:100 ml). After filtering and drying under vacuum, T2 (3.7 g, 79%) was obtained.

¹H NMR (500 MHz, CD₂Cl₂) δ 7.18-6.72 (m, 8H), 2.96 (s, 4H), 2.17 (q, J=7.6 Hz, 4H), 1.00 (t, J=7.6 Hz, 6H).

¹³C NMR (126 MHz, CD₂Cl₂) δ 185.28, 161.41 (d, J=243.4 Hz), 132.47 (d, J=3.2 Hz), 130.34 (d, J=7.9 Hz), 115.44 (d, J=21.6 Hz), 31.23, 27.36, 9.69.

¹¹⁹Sn NMR (186 MHz, CD₂Cl₂) δ −251.42 (t, J=48.9 Hz).

### Synthesis Example 3: Synthesis of T3

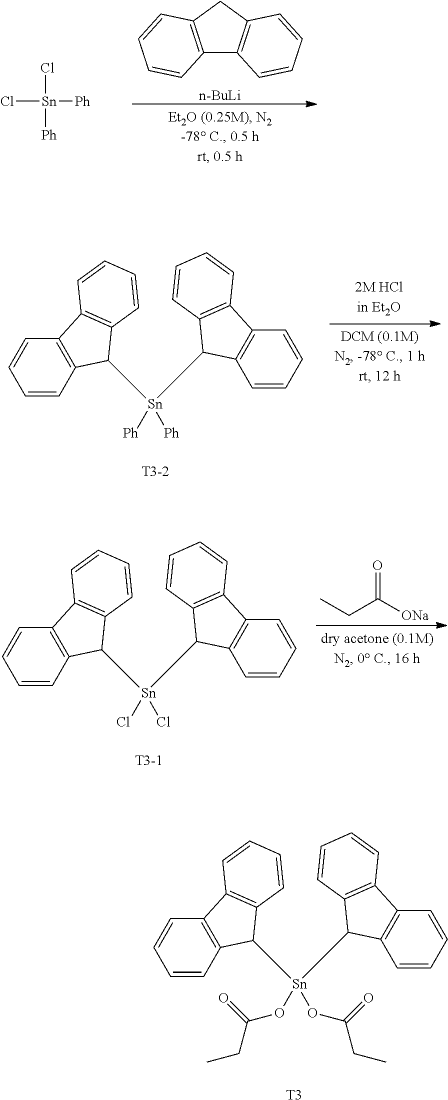

### (1) Synthesis of T3-2

Fluorene (8.31 g, 50.0 mmol) was added to an N₂-substituted 2-neck round bottom flask and diluted with THE (30 ml). n-BuLi (2.5 M in hexane, 20 ml, 50 mmol) was added dropwise at −78° C., and then stirred at 0° C. for 0.5 hours. Dichlorodiphenylstannane (8.60 g, 25.0 mmol) was added to the vial and diluted with THE (50 ml, total THE 100 ml (0.25 M)). The solution in the vial was added dropwise to a round bottom flask at −78° C., stirred for 0.5 hours, then raised to room temperature and stirred again for 0.5 hours. After confirming the completion of the reaction, the solvent was removed, filtered with silica/celite, and purified by column chromatography (dichloromethane (DCM):n-hexane (DCM 10 v %), T3-2 (12.1 g, 80%) was obtained.

¹H NMR (500 MHz, CD₂Cl₂) δ 7.88 (d, J=7.6 Hz, 4H), 7.36-7.23 (m, 10H), 7.23-7.08 (m, 8H), 6.79-6.61 (m, 4H), 4.85 (s, 2H).

¹³C NMR (126 MHz, CD₂Cl₂) δ 145.31, 139.91, 137.35, 137.13, 129.52, 128.51, 126.60, 125.51, 124.18, 120.54, 40.69.

¹¹⁹Sn NMR (186 MHz, CD₂Cl₂) δ −89.93.

### (2) Synthesis of T3-1

T3-2 (12.0 g, 20.0 mmol) was added to a round bottom flask and replaced with N₂. After diluting with dichloromethane (200 ml, 0.1 M), 2M HCl in Et₂O solution (30 ml, 60 mmol) was added dropwise at −78° C. After stirring at −78° C. for 1 hour, the temperature was raised to room temperature and reacted again for 12 hours. After removing the solvent, the precipitate was obtained by washing with n-hexane, and the precipitate was dried under vacuum to obtain T3-1 (8.8 g, 85%).

¹H NMR (500 MHz, CD₂Cl₂) δ 7.70 (d, J=7.6 Hz, 4H), 7.38-7.25 (m, 8H), 7.11 (td, J=7.5, 1.2 Hz, 4H), 4.63 (s, 2H).

¹³C NMR (126 MHz, CD₂Cl₂) δ 140.34, 139.90, 127.61, 127.28, 124.49, 120.90, 50.12.

¹¹⁹Sn NMR (186 MHz, CD₂Cl₂) δ −26.58.

### (3) Synthesis of T3

T3-1 (1.5 g, 2.88 mmol) was added to a round bottom flask and replaced with N₂. After dilution with acetone (29 ml, 0.1 M), sodium propionate (0.55 g, 5.77 mmol) was added at 0° C. After reacting at 0° C. for 16 hours, it was filtered using celite. After removing the solvent, recrystallization was performed (dichloromethane:n-hexane=5 ml:100 ml). After filtering and drying under vacuum, T3 (1.30 g, 76%) was obtained.

¹H NMR (500 MHz, CD₂Cl₂) δ 7.80 (d, J=7.6 Hz, 4H), 7.39-7.26 (m, 8H), 7.17 (td, J=7.5, 1.2 Hz, 4H), 4.52 (s, 2H), 2.04 (q, J=7.5 Hz, 4H), 0.86 (t, J=7.6 Hz, 6H).

¹³C NMR (126 MHz, CD₂Cl₂) δ 185.75, 142.17, 140.73, 126.86, 126.77, 124.87, 120.32, 51.64, 26.85, 9.47.

¹¹⁹Sn NMR (186 MHz, CD₂Cl₂) δ −338.11.

### Preparation Example: Preparation of Casting Solution

The organometallic compounds synthesized in Synthesis Examples 1 to 3 were dissolved at 2 wt % in a casting solvent to prepare Casting solution A-1 to Casting Solution A-3. The additives shown in Table 1 below were added at 2 wt % in ethyl lactate to prepare Casting Solution A-4 and Casting Solution A-5. The organometallic compounds synthesized in Synthesis Examples 1 to 3 were dissolved at 2 wt % in a casting solvent, and further the additives listed in Table 1 below were added so as to the weight ratio of the organometallic compound to additive be 3:1, and Casting Solution B-1 to Casting Solution B-6 were prepared. In addition, the organometallic compound synthesized in Synthesis Example 1 was dissolved in a casting solvent at 2 wt %, and the additives listed in Table 1 below were further added so as to the weight ratio of the organometallic compound to the additive be 4:1, and Casting solution C-1 and Casting Solution C-2 were prepared.

TABLE 1

| | | | Organometallic | |
|---|---|---|---|---|
| Casting | | | compounds: | |
| Solution | organometallic | | additives | |
| No. | compound | additive | (weight ratio) | casting solvent |
| A-1 | T1 | — | 1:0 | ethyl lactate |
| A-2 | T2 | — | 1:0 | ethyl lactate |
| A-3 | T3 | — | 1:0 | ethyl lactate |
| A-4 | — | MR1 | 0:1 | ethyl lactate |
| A-5 | — | MR2 | 0:1 | ethyl lactate |
| B-1 | T1 | MR1 | 3:1 | ethyl lactate |
| B-2 | T1 | MR2 | 3:1 | ethyl lactate |
| B-3 | T2 | MR1 | 3:1 | ethyl lactate |
| B-4 | T2 | MR2 | 3:1 | ethyl lactate |
| B-5 | T3 | MR1 | 3:1 | ethyl lactate |
| B-6 | T3 | MR2 | 3:1 | ethyl lactate |
| C-1 | T1 | MR1 | 4:1 | ethyl lactate |
| C-2 | T1 | MR2 | 4:1 | ethyl lactate |

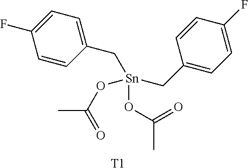

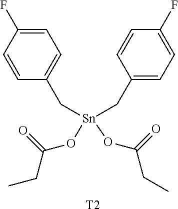 [SMILES: CCC(=O)[O][Sn]([CH2]c1ccc(F)cc1)([CH2]c1ccc(F)cc1)[O]C(=O)CC ; "T2"]

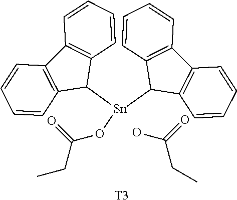

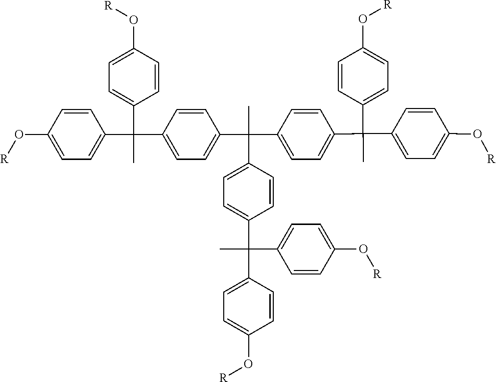

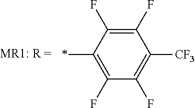 [SMILES: *c1c(F)c(F)c(C(F)(F)F)c(F)c1F]

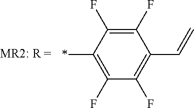 [SMILES: *c1c(F)c(F)c(C=C)c(F)c1F]

### Evaluation Example 1: Surface Roughness (Rq) Evaluation

A silicon wafer coated with a 3 nm lower layer of hexamethyldisilazane (HDMS) was treated with O₂ plasma for 30 minutes, spin-coated with Casting Solution A-1 to Casting Solution A-5, Casting Solution B-1 to Casting Solution B-6, Casting Solution C-1, and Casting Solution C-2 at 1500 rpm for 1 minute each, and then dried (PAB) for 1 minute to 120° C., thereby producing a film having the initial thickness shown in Table 2. Then, a 3.5 mm thick zig (4×4) with rectangular holes (1 cm×1 cm) was placed on the films obtained using the Casting Solution A-1 to A-5, Casting Solution B-1 to B-6, Casting Solution C-1, and C-2, each hole was exposed to deep ultraviolet (DUV) rays at a wavelength of 254 nm with a dose of 60 mJ/cm², and the resultant films were dried (PEB) at 150° C. for 1 minute. The dried films were soaked at 25° C. for 60 seconds using a PGMEA solution including 2 wt % acetic acid as a developer, and then the surface of the remaining films were identified through an atomic force microscope, and Rq was calculated from the average value of the observed light. Next, the relative value of Rq was calculated, and the results are listed in Table 2 below. At this time, the relative values of Examples 1-1, 1-2, 1-7 and 1-8 were calculated based on Comparative Example 1-1, the relative values of Examples 1-3 and 1-4 were calculated based on Comparative Example 1-2, and the relative values of Examples 1-4 and 1-5 were calculated based on Comparative Example 1-3.

TABLE 2

| | | | | Organometallic | | |
|---|---|---|---|---|---|---|
| | Casting | | | compounds: | initial | |
| | Solution | organometallic | | additives | thickness | Rq |
| | No. | compounds | additive | (weight ratio) | (nm) | (%) |
| Comparative | A-1 | T1 | — | 1:0 | 22.0 | 100 |
| Example 1-1 | | | | | | |
| Comparative | A-2 | T2 | — | 1:0 | 23 | 100 |
| Example 1-2 | | | | | | |
| Comparative | A-3 | T3 | — | 1:0 | 22 | 100 |
| Example 1-3 | | | | | | |
| Comparative | A-4 | — | MR1 | 0:1 | n/a | n/a |
| Example 1-4 | | | | | | |
| Comparative | A-5 | — | MR2 | 0:1 | n/a | n/a |
| Example 1-5 | | | | | | |
| Example 1-1 | B-1 | T1 | MR1 | 3:1 | 22.1 | 28 |
| Example 1-2 | B-2 | T1 | MR2 | 3:1 | 23 | 35 |
| Example 1-3 | B-3 | T2 | MR1 | 3:1 | 22 | 25 |
| Example 1-4 | B-4 | T2 | MR2 | 3:1 | 23 | 32 |
| Examples 1-5 | B-5 | T3 | MR1 | 3:1 | 22 | 25 |
| Example 1-6 | B-6 | T3 | MR2 | 3:1 | 22 | 30 |
| Example 1-7 | C-1 | T1 | MR1 | 4:1 | 22 | 41 |
| Examples 1-8 | C-2 | T1 | MR2 | 4:1 | 22 | 37 |

Referring to Table 2, in Comparative Examples 1-4 and 1-5 using each of Casting Solution A-4 and A-5 including only additives, respectively, thin films were not formed and Rq could not be measured.

Referring to Table 2, Examples 1-1 to 1-8 including additives show significantly lower Rq compared to Comparative Examples 1-1 to 1-3, respectively, confirming that the coating properties of the resist composition including additives are improved.

### Evaluation Example 2: Evaluation of Thin Film Development

A silicon wafer coated with a 3 nm lower layer of HDMS was treated with O₂ plasma for 30 minutes, spin-coated with Casting Solution A-1 to A-5, Casting Solution B-1 to B-6, Casting Solution C-1, and C-2 at 1500 rpm for 1 minute each, and then dried (PAB) for 1 minute to 120° C. to produce a film. Then, a 3.5 mm thick zig (4×4) with rectangular holes (1 cm×1 cm) was placed on the films obtained using the Casting Solution A-1 to Casting Solution A-5, Casting Solution B-1 to Casting Solution B-6, Casting Solution C-1, and Casting Solution C-2, each hole was exposed to deep ultraviolet (DUV) rays at a wavelength of 254 nm with a dose of 60 mJ/cm², and the resultant structure was dried (PEB) at 150° C. for 1 minute. The dried films were soaked at 25° C. for 60 seconds using a PGMEA solution including 2 wt % acetic acid as a developer, and then the thickness of the remaining films was determined and shown in Table 3. At this time, the relative values of Examples 2-1, 2-2, 2-7 and 2-8 were calculated based on Comparative Example 2-1, the relative values of Examples 2-3 and 2-4 were calculated based on Comparative Example 2-2, and the relative values of Examples 2-4 and 2-5 were calculated based on Comparative Example 2-3.

TABLE 3

| | | | | Organometallic | | | |
|---|---|---|---|---|---|---|---|
| | casting | | | compounds: | initial | | |
| | Solution | organometallic | | additives | thickness | Eₜₕ | E₁ |
| | No. | compounds | additive | (weight ratio) | (nm) | (%) | (%) |
| Comparative | A-1 | T1 | — | 1:0 | 22.0 | 100 | 100 |
| Example 2-1 | | | | | | | |
| Comparative | A-2 | T2 | — | 1:0 | 23 | 100 | 100 |
| Example 2-2 | | | | | | | |
| Comparative | A-3 | T3 | — | 1:0 | 22 | 100 | 100 |
| Example 2-3 | | | | | | | |
| Comparative | A-4 | — | MR1 | 0:1 | n/a | n/a | n/a |
| Example 2-4 | | | | | | | |
| Comparative | A-5 | — | MR2 | 0:1 | n/a | n/a | n/a |
| Example 2-5 | | | | | | | |
| Example 2-1 | B-1 | T1 | MR1 | 3:1 | 22.1 | 85 | 93 |
| Example 2-2 | B-2 | T1 | MR2 | 3:1 | 23 | 81 | 91 |
| Example 2-3 | B-3 | T2 | MR1 | 3:1 | 22 | 74 | 87 |
| Example 2-4 | B-4 | T2 | MR2 | 3:1 | 23 | 65 | 75 |
| Example 2-5 | B-5 | T3 | MR1 | 3:1 | 22 | 50 | 70 |
| Example 2-6 | B-6 | T3 | MR2 | 3:1 | 22 | 48 | 70 |
| Example 2-7 | C-1 | T1 | MR1 | 4:1 | 22 | 81 | 91 |
| Example 2-8 | C-2 | T1 | MR2 | 4:1 | 22 | 81 | 91 |

In Table 3, Eₜₕ refers to the exposure amount at the point when a thin film begins to harden, and E₁ refers to the exposure amount at the saturation point where the thickness of the thin film no longer increases.

Referring to Table 3, in Comparative Examples 2-4 and 2-5 using Casting Solution A-4 and Casting Solution A-S including only additives, thin films were not formed, respectively, and Eₜₕ and E₁ could not be measured.

Referring to Table 3, it can be seen that Eₜₕ and E₁ of Examples 2-1 to 2-8 have smaller values than Eₜₕ and E₁ of Comparative Examples 2-1 to 2-3, and from this, it can be confirmed that the photosensitivity was improved when the additive is used.

According to the embodiments, a resist composition having improved storage stability and improved sensitivity and providing a pattern with increased resolution may be provided.

It should be understood that the example embodiments described herein should be considered in a descriptive sense only and not for purposes of limitation. Descriptions of features or aspects within each of the example embodiments should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A resist composition comprising:
an organometallic compound represented by Formula 1; and
an additive represented by Formula 2; 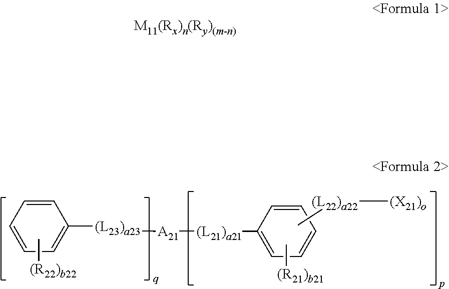
wherein in Formulae 1 and 2,
M₁₁ is indium (In), tin (Sn), antimony (Sb), tellurium (Te), thallium (Tl), lead (Pb), bismuth (Bi), or polonium (Po),
Rₓ is *-(L₁)ₐ₁-(R₁)_{b1},
R_{y} is *-Y₁-X₁,
* is a bonding site with a neighboring atom of Formula 1,
n is an integer from 1 to 6,
m is an integer from 0 to 6,
m-n is greater than or equal to 0,
a plurality of Rₓ are the same or different from each other,
a plurality of R_{y} are the same or different from each other,
L₁ is a single bond, a linear or branched C₁-C₃₀ divalent hydrocarbon group, or a cyclic C₃-C₃₀ divalent hydrocarbon group,
a1 is an integer from 1 to 4,
R₁ is a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, substituted or unsubstituted C₃-C₃₀ heterocycloalkenyl group, substituted or unsubstituted C₂-C₃₀ alkynyl group, substituted or unsubstituted C₆-C₃₀ aryl group, substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
b1 is an integer from 1 to 4, such that Rₓ includes,
a single R₁ based on b1 being 1, or
a plurality of R₁ based on b1 being 2, 3, or 4, the plurality of R₁ being independently present or adjacent two of the plurality of R₁ being combined with each other to form a condensed ring,
Y₁ is O, O(C═O), S, S(C═O), NX₁₄ or N(C═O),
X₁ and X₁₄ are each independently hydrogen, deuterium, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom,
A₂₁ is a single bond, a substituted or unsubstituted carbon atom, a substituted or unsubstituted silicon atom, or (p+q)-valent bonding unit;
L₂₁ to L₂₃ are each independently a single bond; O; S; CO; CO₂; a hydroxyl group; a cyano group; a nitro group; a linear or branched C₁-C₃₀ divalent hydrocarbon group; a linear or branched C₁-C₃₀ divalent hydrocarbon group including a heteroatom; a cyclic C₃-C₃₀ divalent hydrocarbon group; a cyclic C₃-C₃₀ divalent hydrocarbon group including a heteroatom; a linear or branched C₁-C₃₁ monovalent hydrocarbon group; a linear or branched C₁-C₃₁ monovalent hydrocarbon group including a heteroatom, a cyclic C₃-C₃₁ monovalent hydrocarbon group; a cyclic C₃-C₃₁ monovalent hydrocarbon group including a heteroatom; or any combination thereof,
a₂₁ to a₂₃ are each independently an integer from 1 to 6;
R₂₁ and R₂₂ are each independently hydrogen, deuterium, a halogen atom, a hydroxyl group, a cyano group, a nitro group, a linear or branched C₁-C₃₀ monovalent hydrocarbon group, a linear or branched C₁-C₃₀ monovalent hydrocarbon group including a heteroatom, a cyclic C₃-C₃₀ monovalent hydrocarbon group, or a cyclic C₃-C₃₀ monovalent hydrocarbon group including a heteroatom,
b21 is an integer from 1 to 4,
b22 is an integer from 1 to 5,
X₂₁ is a substituted or unsubstituted C₁-C₃₀ alkyl group, a substituted or unsubstituted C₁-C₃₀ haloalkyl group, a substituted or unsubstituted C₂-C₃₀ alkenyl group, or a substituted or unsubstituted C₆-C₃₀ aryl group,
is an integer from 1 to 10,
p is an integer from 1 to 10,
q is an integer from 0 to 10, and
A₂₁, L₂₁ to L₂₃, R₂₁, and R₂₂ are each independently present or adjacent two of A₂₁, L₂₁ to L₂₃, R₂₁, and R₂₂ are combined with each other to form a ring.

2. The resist composition of claim 1,
wherein M₁₁ is In, Sn, or Sb.

3. The resist composition of claim 1,
wherein n is an integer from 1 to 4, and
m is an integer from 0 to 3.

4. The resist composition of claim 1,
wherein L₁ is a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or substituted or unsubstituted C₁-C₃₀ heteroarylene group.

5. The resist composition of claim 1,
wherein R₁ is a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

6. The resist composition of claim 1,
wherein Y₁ is O, O(C═O), S or S(C═O).

7. The resist composition of claim 1,
wherein X₁ and X₁₄ are each independently hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group and a C₂-C₃₀ heteroarylalkyl group, each unsubstituted or substituted with deuterium, a halogen atom, a cyano group, a nitro group, a hydroxy group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

8. The resist composition of claim 1,
wherein the organometallic compound represented by Formula 1 is represented by any one of Formulae 1-1 to 1-4: 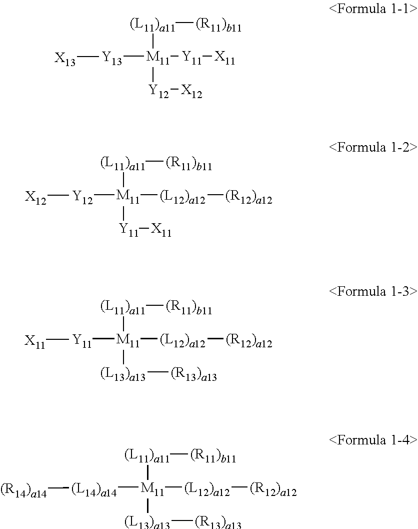
wherein in Formulae 1-1 to 1-4,
M₁₁ has a same composition as defined in Formula 1,
L₁₁ to L₁₄ each independently have a same composition as L₁ in Formula 1,
a₁₁ to a₁₄ each independently have a same composition as a₁ in Formula 1,
R₁₁ to R₁₄ each independently have a same composition as R₁ in Formula 1,
b₁₁ to b₁₄ each independently have a same composition as b₁ in Formula 1,
Y₁₁ to Y₁₃ each independently have a same composition as Y₁ in Formula 1, and
X₁₁ to X₁₄ each independently have a same composition as X₁ in Formula 1.

9. The resist composition of claim 1,
wherein the organometallic compound represented by Formula 1 is selected from Group I: 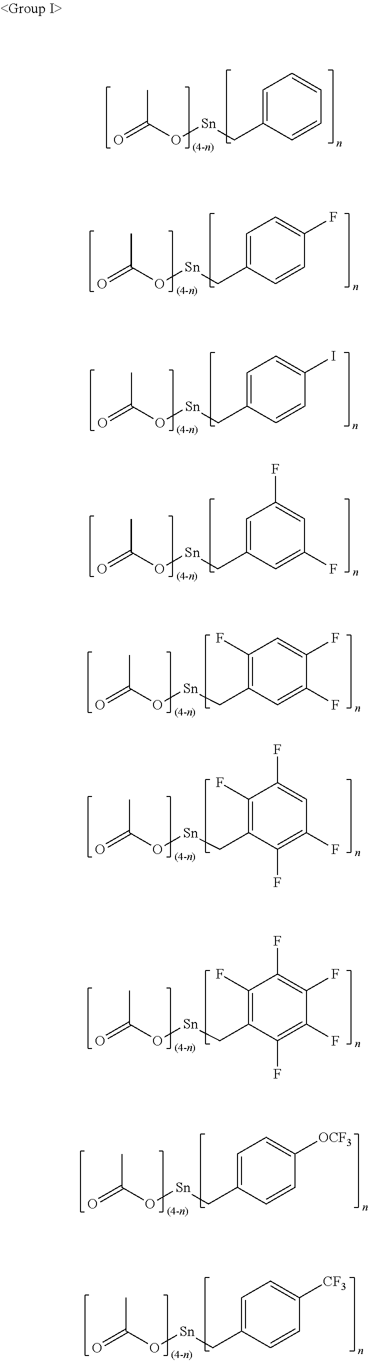 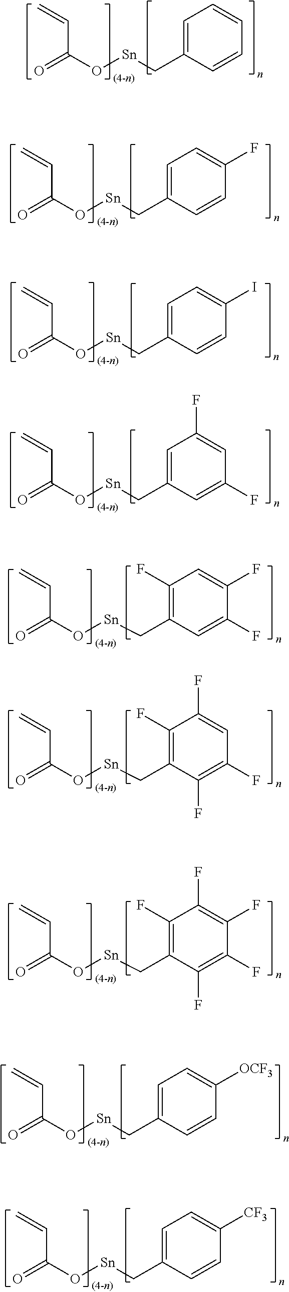 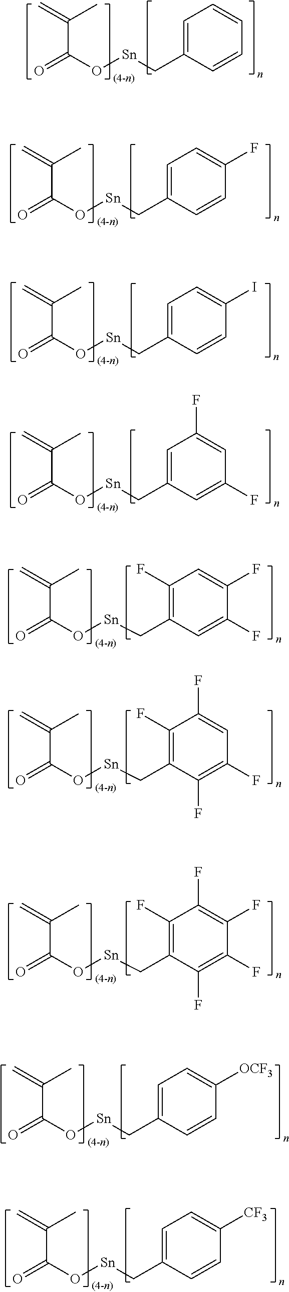 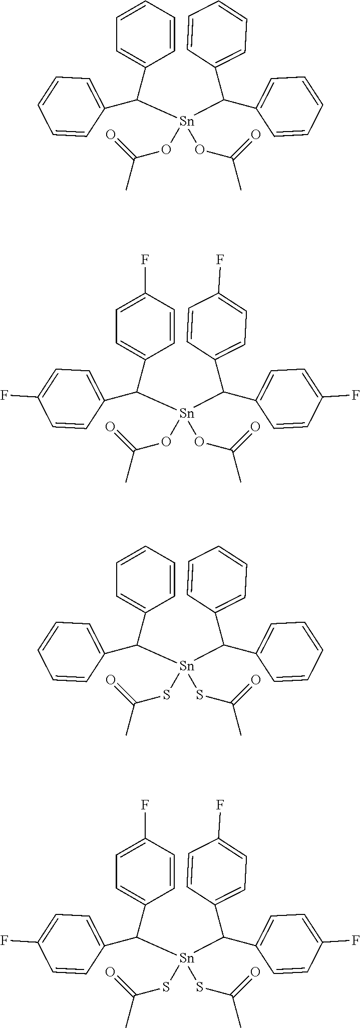 [SMILES: CC(=O)[O][Sn]([O]C(C)=O)([CH](c1ccccc1)c1ccccc1)[CH](c1ccccc1)c1ccccc1 ; CC(=O)[O][Sn]([O]C(C)=O)([CH](c1ccc(F)cc1)c1ccc(F)cc1)[CH](c1ccc(F)cc1)c1ccc(F)cc1 ; CC(=O)[S][Sn]([S]C(C)=O)([CH](c1ccccc1)c1ccccc1)[CH](c1ccccc1)c1ccccc1 ; CC(=O)[S][Sn]([S]C(C)=O)([CH](c1ccc(F)cc1)c1ccc(F)cc1)[CH](c1ccc(F)cc1)c1ccc(F)cc1] 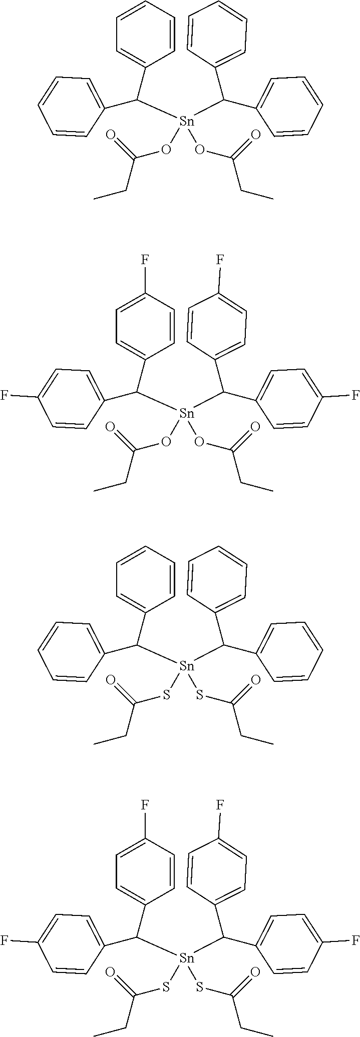 [SMILES: CCC(=O)[O][Sn]([O]C(=O)CC)([CH](c1ccccc1)c1ccccc1)[CH](c1ccccc1)c1ccccc1 ; CCC(=O)[O][Sn]([O]C(=O)CC)([CH](c1ccc(F)cc1)c1ccc(F)cc1)[CH](c1ccc(F)cc1)c1ccc(F)cc1 ; CCC(=O)[S][Sn]([S]C(=O)CC)([CH](c1ccccc1)c1ccccc1)[CH](c1ccccc1)c1ccccc1 ; CCC(=O)[S][Sn]([S]C(=O)CC)([CH](c1ccc(F)cc1)c1ccc(F)cc1)[CH](c1ccc(F)cc1)c1ccc(F)cc1] 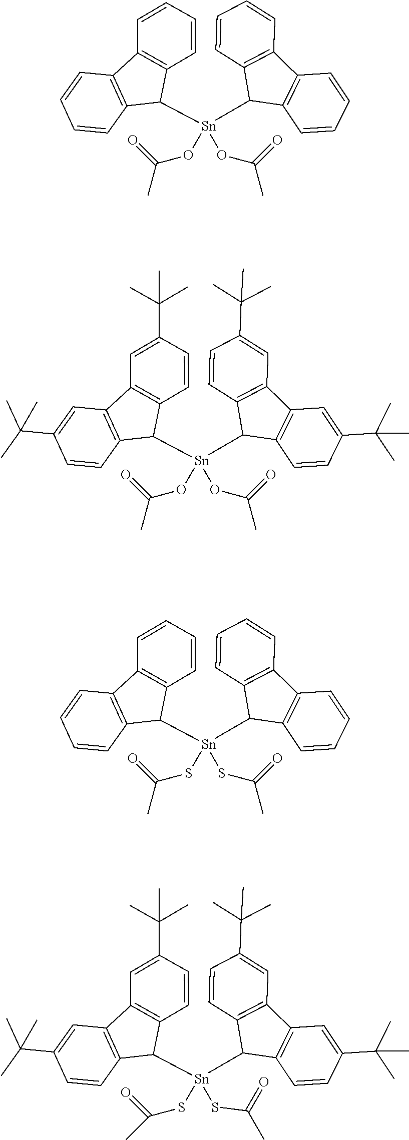 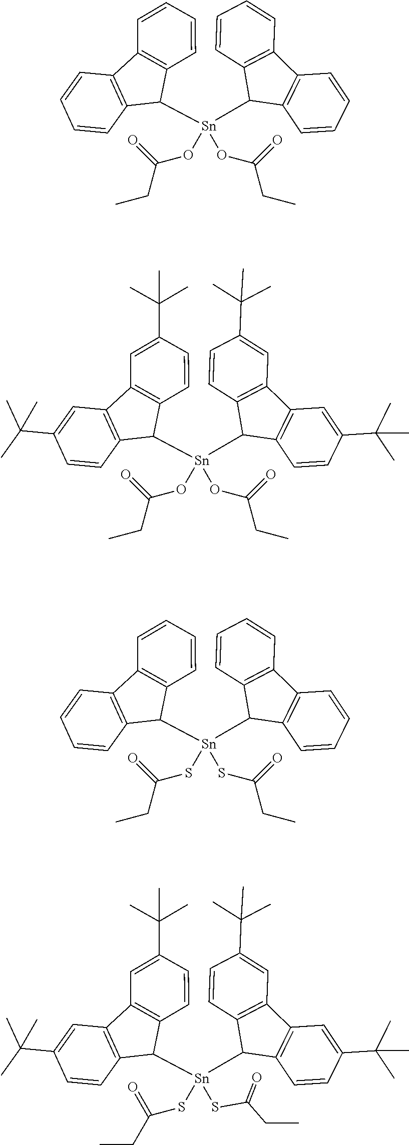 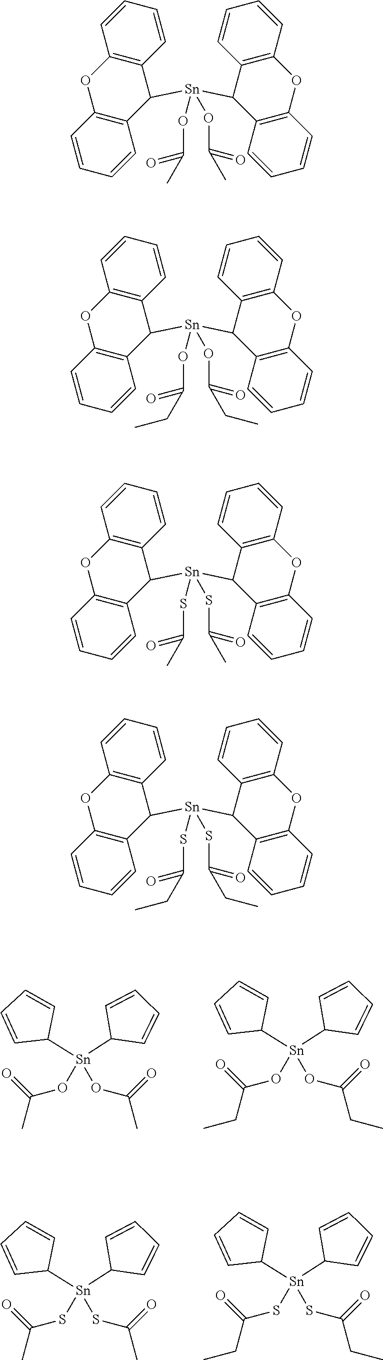 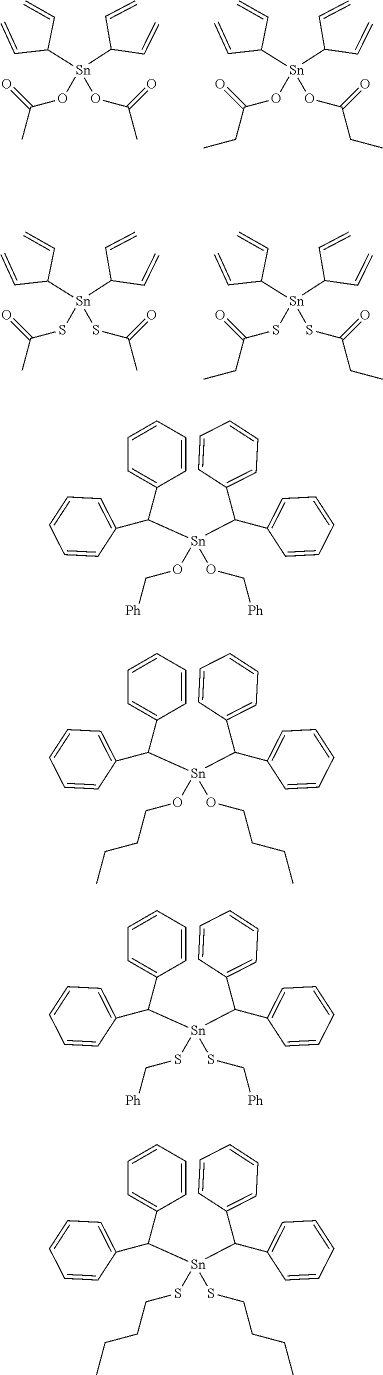 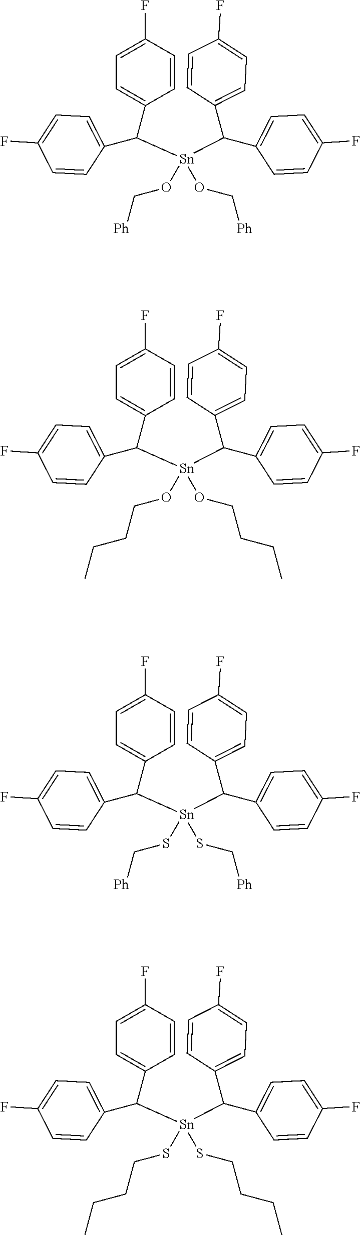 [SMILES: Fc1ccc([CH](c2ccc(F)cc2)[Sn]([O]Cc2ccccc2)([O]Cc2ccccc2)[CH](c2ccc(F)cc2)c2ccc(F)cc2)cc1 ; CCCC[O][Sn]([O]CCCC)([CH](c1ccc(F)cc1)c1ccc(F)cc1)[CH](c1ccc(F)cc1)c1ccc(F)cc1 ; Fc1ccc([CH](c2ccc(F)cc2)[Sn]([S]Cc2ccccc2)([S]Cc2ccccc2)[CH](c2ccc(F)cc2)c2ccc(F)cc2)cc1 ; CCCC[S][Sn]([S]CCCC)([CH](c1ccc(F)cc1)c1ccc(F)cc1)[CH](c1ccc(F)cc1)c1ccc(F)cc1] 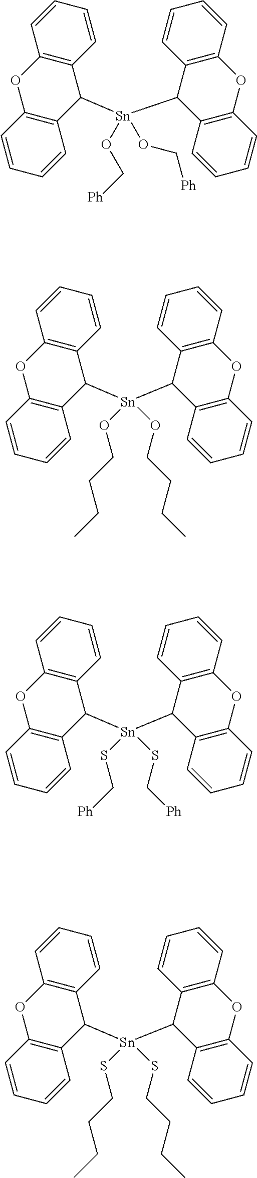 [SMILES: c1ccc(C[O][Sn]([O]Cc2ccccc2)([CH]2c3ccccc3Oc3ccccc32)[CH]2c3ccccc3Oc3ccccc32)cc1 ; CCCC[O][Sn]([O]CCCC)([CH]1c2ccccc2Oc2ccccc21)[CH]1c2ccccc2Oc2ccccc21 ; c1ccc(C[S][Sn]([S]Cc2ccccc2)([CH]2c3ccccc3Oc3ccccc32)[CH]2c3ccccc3Oc3ccccc32)cc1 ; CCCC[S][Sn]([S]CCCC)([CH]1c2ccccc2Oc2ccccc21)[CH]1c2ccccc2Oc2ccccc21] 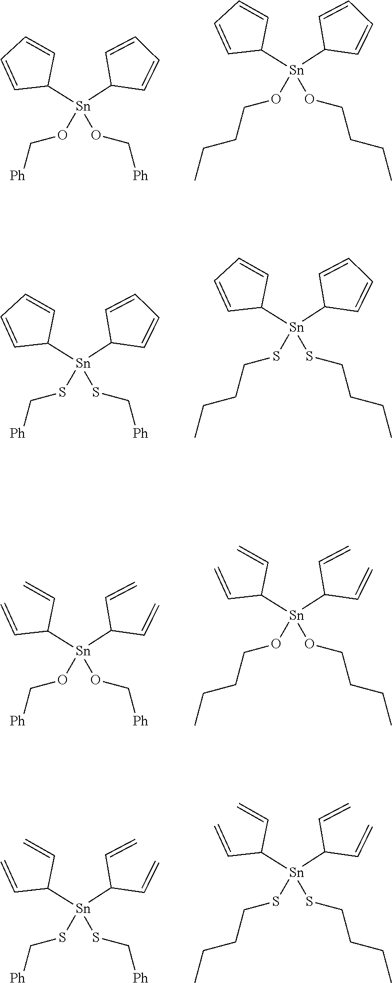 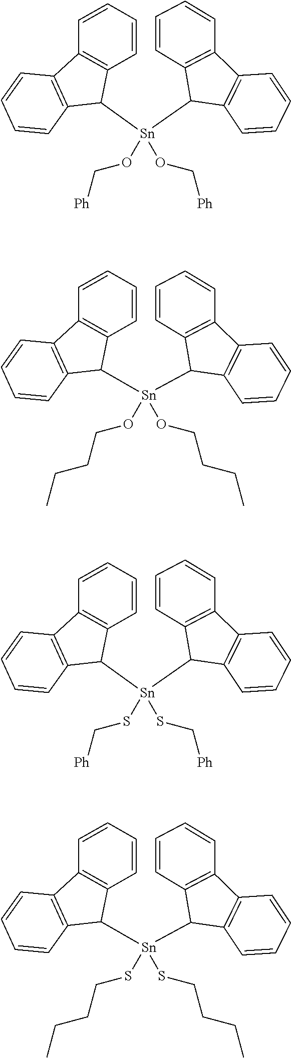 [SMILES: c1ccc(C[O][Sn]([O]Cc2ccccc2)([CH]2c3ccccc3-c3ccccc32)[CH]2c3ccccc3-c3ccccc32)cc1 ; CCCC[O][Sn]([O]CCCC)([CH]1c2ccccc2-c2ccccc21)[CH]1c2ccccc2-c2ccccc21 ; c1ccc(C[S][Sn]([S]Cc2ccccc2)([CH]2c3ccccc3-c3ccccc32)[CH]2c3ccccc3-c3ccccc32)cc1 ; CCCC[S][Sn]([S]CCCC)([CH]1c2ccccc2-c2ccccc21)[CH]1c2ccccc2-c2ccccc21] 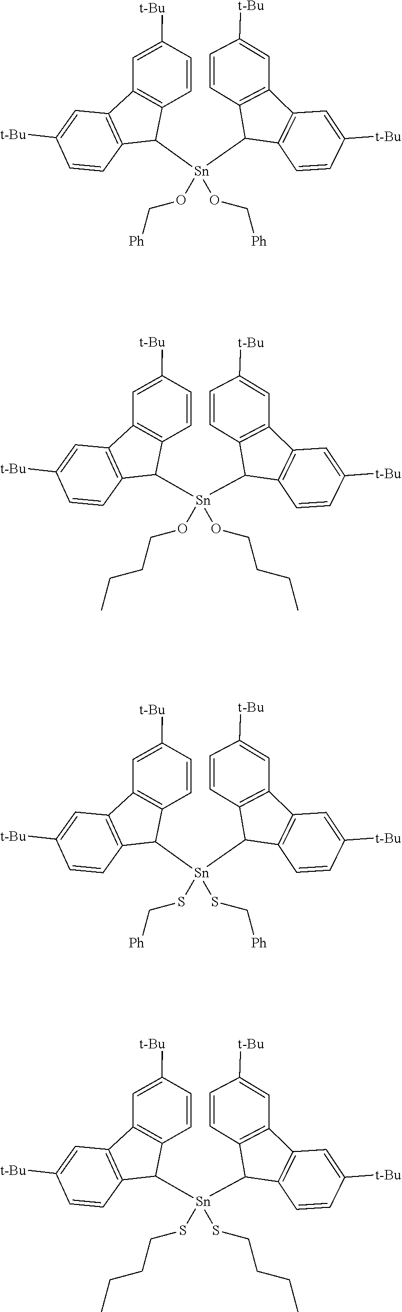 [SMILES: CC(C)(C)c1ccc2c(c1)-c1cc(C(C)(C)C)ccc1[CH]2[Sn]([O]Cc1ccccc1)([O]Cc1ccccc1)[CH]1c2ccc(C(C)(C)C)cc2-c2cc(C(C)(C)C)ccc21 ; CCCC[O][Sn]([O]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21 ; CC(C)(C)c1ccc2c(c1)-c1cc(C(C)(C)C)ccc1[CH]2[Sn]([S]Cc1ccccc1)([S]Cc1ccccc1)[CH]1c2ccc(C(C)(C)C)cc2-c2cc(C(C)(C)C)ccc21 ; CCCC[S][Sn]([S]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21]
wherein in Group I, n is an integer from 1 to 4.

10. The resist composition of claim 1,
wherein A₂₁ is a single bond, a substituted or unsubstituted carbon atom, or (p+q)-valent bonding unit including at least one of a substituted or unsubstituted carbon atom or substituted or unsubstituted benzene as a repeating unit.

11. The resist composition of claim 1,
wherein L₂₁ to L₂₃ are each independently a single bond, O, S, CO, CO₂, CRₐR_{b}, or any combination thereof, and
Rₐ and R_{b} are each independently hydrogen, deuterium, a halogen atom, a hydroxyl group, a cyano group, a nitro group, or a linear or branched C₁-C₁₀ monovalent hydrocarbon group, a linear or branched C₁-C₁₀ monovalent hydrocarbon group including a heteroatom, a cyclic C₃-C₁₀ monovalent hydrocarbon group, or a cyclic C₃-C₁₀ monovalent hydrocarbon group including a heteroatom.

12. The resist composition of claim 1,
wherein R₂₁ and R₂₂ are each independently hydrogen, deuterium, a halogen atom, a hydroxyl group, a cyano group, a nitro group, a substituted or unsubstituted C₁-C₃₀ alkyl group, a substituted or unsubstituted C₃-C₃₀ cycloalkyl group, a substituted or unsubstituted C₂-C₃₀ alkenyl group, a substituted or unsubstituted C₃-C₃₀ cycloalkenyl group, a substituted or unsubstituted C₂-C₃₀ alkynyl group, or a substituted or unsubstituted C₆-C₃₀ aryl group.

13. The resist composition of claim 1,
wherein X₂₁ is a substituted or unsubstituted C₁-C₁₀ haloalkyl group, a substituted or unsubstituted vinyl group, or a group represented by Formula 5-1: 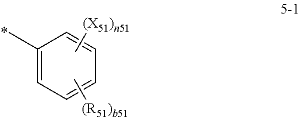
wherein in Formula 5-1,
X₅₁ is a halogen atom, a substituted or unsubstituted C₁-C₁₀ haloalkyl group, or a substituted or unsubstituted vinyl group,
n51 is an integer from 1 to 5,
R₅₁ is hydrogen, deuterium, a halogen atom, a hydroxyl group, a substituted or unsubstituted C₁-C₁ haloalkyl group, or a substituted or unsubstituted vinyl group,
b51 is an integer from 0 to 4, and
* is a bonding site with a neighboring atom of Formula 2.

14. The resist composition of claim 1,
wherein the additive represented by Formula 2 is represented by Formula 2-1: 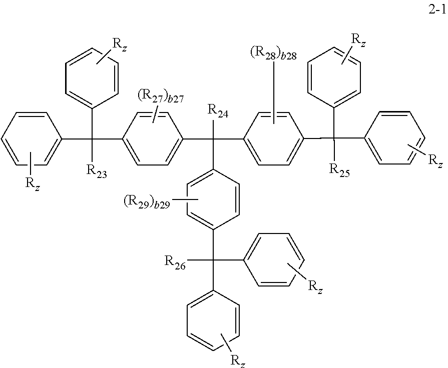
wherein in Formula 2-1,
R_{z} is selected from R₂₂ and (L₂₂)ₐ₂₂-(X₂₁)ₒ, at least one of R_{z} is (L₂₂)ₐ₂₂-(X₂₁)ₒ,
R₂₂ to R₂₉ are each independently the same as the definition of R₂₂ in Formula 2, and
b27 to b29 are each independently an integer of 1 to 4.

15. The resist composition of claim 1,
wherein the additive represented by Formula 2 is selected from Group II: 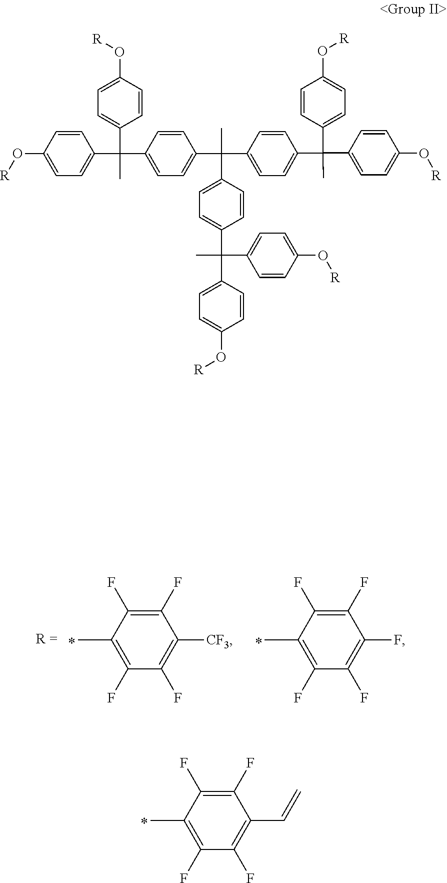
wherein in Group II,
* is a bonding site with a neighboring atom of Formula 2, and
each R is independently one of

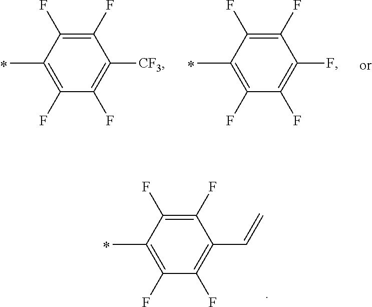

16. The resist composition of claim 1,
wherein the additive is included in an amount of 0.1 parts by weight to 100,000 parts by weight, based on 100 parts by weight of the organometallic compound.

17. A method of forming a pattern, comprising:
applying the resist composition of claim 1 onto a substrate to form a resist film;
exposing at least a portion of the resist film to high-energy rays to provide an exposed resist film; and
developing the exposed resist film using a developer.

18. The method of forming a pattern of claim 17,
wherein the exposing at least a portion of the resist film is performed based on irradiating the resist film using at least one of deep ultraviolet rays (DUV), extreme ultraviolet rays (EUV), electron beams (EBs), or any combination thereof.

19. The method of forming a pattern of claim 17,
wherein the organometallic compound is subjected to a condensation reaction based on exposing the resist film.

20. The method of forming a pattern of claim 17,
wherein the exposed resist film includes an exposed portion and a non-exposed portion, and
in the developing, the non-exposed portion is removed.
